(19) United States
(12) Patent Application Publication
(10) Pub. No.: US 2026/0247778 A1
(43) Pub. Date: Aug. 20, 2026

(54) DISPLAY DEVICE AND ELECTRONIC DEVICE

(71) Applicant: Samsung Display Co., Ltd., Yongin-si (KR)

(72) Inventors: Ki Su JIN, Yongin-si (KR); Jae Gwang UM, Yongin-si (KR); Tae Hee LEE, Yongin-si (KR); Moon Won CHANG, Yongin-si (KR)

(21) Appl. No.: 19/396,160

(22) Filed: Nov. 20, 2025

(30) Foreign Application Priority Data
Feb. 18, 2025 (KR) 10-2025-0020694

(51) Int. Cl. H10H 29/856; H10H 29/37

(52) U.S. Cl. CPC H10H 29/856; H10H 29/37

(57) ABSTRACT

A display device includes: a pixel electrode located on a substrate; and a light emitting element located on the pixel electrode and electrically connected to the pixel electrode, wherein the light emitting element includes: a semiconductor stack including a first semiconductor layer, an active layer, and a second semiconductor layer; a protective film covering a side surface of the semiconductor stack; and a first contact electrode located on a side surface of the protective film and electrically connected to the first semiconductor layer, wherein the first contact electrode includes a transparent conductive material.

### CROSS-REFERENCE TO RELATED APPLICATION

This application claims priority to and the benefit of Korean Patent Application No. 10-2025-0020694, filed on February 18, 2025, in the Korean Intellectual Property Office, the entire disclosure of which is incorporated by reference herein.

### BACKGROUND

### 1. Field

Embodiments of the present disclosure relate to a display device and an electronic device capable of displaying an image.

### 2. Description of the Related Art

With the advance of information-oriented society, more and more demands are placed on display devices and electronic devices capable of displaying images in various ways. Accordingly, various types of display devices and electronic devices including pixels for displaying images are being developed. A display device may be provided alone, or may be included in an electronic device and used as a display screen of the electronic device.

### SUMMARY

Aspects and features of embodiments of the present disclosure provide a display device and an electronic device capable of improving light efficiency.

However, aspects and features of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including: a pixel electrode located on a substrate; and a light emitting element located on the pixel electrode and electrically connected to the pixel electrode, wherein the light emitting element includes: a semiconductor stack including a first semiconductor layer, an active layer, and a second semiconductor layer; a protective film covering a side surface of the semiconductor stack; and a first contact electrode located on a side surface of the protective film and electrically connected to the first semiconductor layer, wherein the first contact electrode includes a transparent conductive material.

In one or more embodiments, the display device further includes: a bank spaced from the light emitting element and around the light emitting element; and a reflective film located on a side surface of the bank.

In one or more embodiments, the reflective film faces the side surface of the light emitting element.

In one or more embodiments, the first contact electrode includes indium-tin oxide or indium-zinc oxide.

In one or more embodiments, the first contact electrode is located on a portion of each of a side surface and a bottom surface of the light emitting element.

In one or more embodiments, the display device further includes: a first conductive pattern located between a portion of the pixel electrode and a bottom surface of the first contact electrode; and a first connection electrode located on another portion of the pixel electrode, a side surface of the first contact electrode, and a side surface of the first conductive pattern.

In one or more embodiments, the light emitting element further includes a second contact electrode located on another portion of each of the side surface and the bottom surface of the light emitting element and is electrically connected to the second semiconductor layer, and wherein the second contact electrode includes a transparent conductive material.

In one or more embodiments, the display device further includes: a common electrode located on the substrate and spaced from the pixel electrode; a second conductive pattern located between a portion of the common electrode and a bottom surface of the second contact electrode; and a second connection electrode located on another portion of the common electrode, a side surface of the second contact electrode, and a side surface of the second conductive pattern.

In one or more embodiments, the first conductive pattern and the second conductive pattern include a conductive photoresist.

In one or more embodiments, the first conductive pattern and the second conductive pattern include carbon black.

In one or more embodiments, the first connection electrode and the second connection electrode include a transparent conductive material.

In one or more embodiments, the display device further includes: an organic layer located between the pixel electrode and the light emitting element and covering a portion of the pixel electrode; and a first connection electrode located on a portion of the organic layer and electrically connecting the pixel electrode and the first contact electrode.

In one or more embodiments, the light emitting element further includes a second contact electrode located on the side surface of the protective film, spaced from the first contact electrode, and electrically connected to the second semiconductor layer, and wherein the second contact electrode includes a transparent conductive material.

In one or more embodiments, the display device further includes: a common electrode located on the substrate and spaced from the pixel electrode; an organic layer covering a portion of the common electrode and the pixel electrode and located below the light emitting element; a first connection electrode located on a portion of the organic layer and electrically connecting the pixel electrode and the first contact electrode; and a second connection electrode located on another portion of the organic layer and electrically connecting the common electrode and the second contact electrode.

In one or more embodiments, an electronic device includes: a display module including a display panel; and a processor configured to transmit an image data signal to the display module, wherein the display panel includes: a pixel electrode located on a substrate; and a light emitting element located on the pixel electrode and electrically connected to the pixel electrode, wherein the light emitting element includes: a semiconductor stack including a first semiconductor layer, an active layer, and a second semiconductor layer; a protective film covering a side surface of the semiconductor stack; and a first contact electrode located on a side surface of the protective film and electrically connected to the first semiconductor layer, the first contact electrode including a transparent conductive material.

In one or more embodiments, the display panel further includes: a bank spaced from the light emitting element and around the light emitting element; and a reflective film located on a side surface of the bank.

In one or more embodiments, the first contact electrode is located on a portion of each of a side surface and a bottom surface of the light emitting element, and wherein the display panel further includes: a first conductive pattern located between a portion of the pixel electrode and a bottom surface of the first contact electrode; and a first connection electrode located on another portion of the pixel electrode, a side surface of the first contact electrode, and a side surface of the first conductive pattern.

In one or more embodiments, the first conductive pattern includes a conductive photoresist.

In one or more embodiments, the light emitting element further includes a second contact electrode located on the side surface of the protective film, spaced from the first contact electrode, and electrically connected to the second semiconductor layer, and wherein the second contact electrode includes a transparent conductive material.

In one or more embodiments, the display panel further includes: a common electrode located on the substrate and spaced from the pixel electrode; a first connection electrode located on the pixel electrode and electrically connecting the pixel electrode and the first contact electrode; and a second connection electrode located on the common electrode and electrically connecting the common electrode and the second contact electrode.

The display device and the electronic device according to one or more embodiments may include a light emitting element including a contact electrode located at a side surface thereof, and the contact electrode may include a transparent conductive material. In one or more embodiments, the display device and the electronic device may further include a reflective film located around the light emitting element. According to one or more embodiments, the light emission ratio of light generated from the light emitting element may be increased, and the luminance and light efficiency of the display device and the electronic device may be improved.

In one or more embodiments, the display device and the electronic device may further include a conductive pattern located between a pixel electrode layer including a pixel electrode and a light emitting element, and a connection electrode located on a side surface of the light emitting element. According to one or more embodiments, the light emitting element may be more stably located on the pixel electrode layer, and the contact resistance between the pixel electrode layer and the light emitting element may be reduced. Accordingly, the electrical characteristics and reliability of the display device and the electronic device may be improved.

However, effects, aspects, and features, of embodiments of the present disclosure are not limited to those discussed above and various other effects, aspects, and features are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to one or more embodiments;

FIG. 2 is a layout view illustrating a display device according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is a plan view illustrating a display area of a display panel according to one or more embodiments;

FIG. 6 is a cross-sectional view illustrating a display area of a display panel according to one or more embodiments;

FIG. 7 is a cross-sectional view showing an area A1 of FIG. 6 in detail;

FIG. 8 is a cross-sectional view illustrating a display area of a display panel according to one or more embodiments;

FIG. 9 is a cross-sectional view illustrating a display area of a display panel according to one or more embodiments;

FIG. 10 is a plan view illustrating a display area of a display panel according to one or more embodiments;

FIG. 11 is a cross-sectional view illustrating a display area of a display panel according to one or more embodiments;

FIG. 12 is a cross-sectional view showing an area A2 of FIG. 11 in detail;

FIG. 13 is a block diagram of an electronic device according to one or more embodiments; and

FIG. 14 is schematic views of electronic devices according to various embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when an element or a layer is referred to as being "on" another element or layer, it can be directly on the other element or layer, or intervening layers may also be present. The same reference numbers indicate the same components throughout the specification.

It will be understood that, although the terms "first," "second," etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Further, the phrase "in a plan view" means when an object portion is viewed from above, and the phrase "in a schematic cross-sectional view" means when a schematic cross-section taken by vertically cutting an object portion is viewed from the side. The terms "overlap" or "overlapped" mean that a first object may be above or below or to a side of a second object, and vice versa. Additionally, the term "overlap" may include layer, stack, face or facing, extending over, covering, or partly covering or any other suitable term as would be appreciated and understood by those of ordinary skill in the art. The expression "not overlap" may include meaning such as "apart from" or "set aside from" or "offset from" and any other suitable equivalents as would be appreciated and understood by those of ordinary skill in the art. The terms "face" and "facing" may mean that a first object may directly or indirectly oppose a second object. In a case in which a third object intervenes between a first and second object, the first and second objects may be understood as being indirectly opposed to one another, although still facing each other.

The spatially relative terms "below," "beneath," "lower," "above," "upper," and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned "below" or "beneath" another device may be placed "above" another device. Accordingly, the illustrative term "below" may include both the lower and upper positions. The device may also be oriented in other directions and thus the spatially relative terms may be interpreted differently depending on the orientations.

When an element is referred to as being "connected" or "coupled" to another element, the element may be "directly connected" or "directly coupled" to another element, or "electrically connected" or "electrically coupled" to another element with one or more intervening elements interposed therebetween. It will be further understood that when the terms "comprises," "comprising," "has," "have," "having," "includes" and/or "including" are used, they may specify the presence of stated features, integers, steps, operations, elements and/or components, but do not preclude the presence or addition of other features, integers, steps, operations, elements, components, and/or any combination thereof.

The terms "about" or "approximately" as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, "about" may mean within one or more standard deviations, or within ± 30%, 20%, 10%, 5% of the stated value.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or." In the specification and the claims, the phrase "at least one of" is intended to include the meaning of "at least one selected from the group of" for the purpose of its meaning and interpretation. For example, "at least one of A and B" may be understood to mean "A, B, or A and B."

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Features of each of various embodiments of the present disclosure may be partially or entirely combined with each other and may technically variously interwork with each other, and respective embodiments may be implemented independently of each other or may be implemented together in association with each other.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

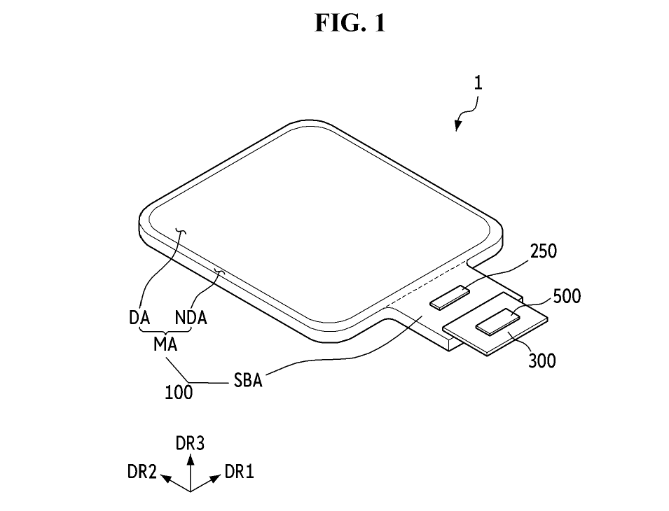

FIG. 1 is a perspective view illustrating a display device according to one or more embodiments.

Referring to FIG. 1, a display device 1 may be a device capable of providing an image, such as a moving image and/or a still image. For example, the display device 1 may be a device that includes a display module including a display panel 100 and thus may display an image. As an example, the display device 1 may refer to all electronic devices that provide a display screen on which an image may be displayed or include a display module for displaying an image.

The display device 1 may be provided alone, or may be included in an electronic device providing a display screen to form the display screen of the electronic device. For example, the display device 1 may be included in various electronic devices such as televisions, laptop computers, monitors, billboards and the Internet of Things (IOT) as well as portable electronic devices such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs), and used as a display screen. In addition, the display device 1 may be included in other electronic devices such as a virtual reality (VR) device, an augmented reality (AR) device, and/or the like and used to display an image in the electronic device. In one or more embodiments, the electronic device including the display device 1 may further include a display device housing in which the display device 1 is accommodated and/or a case or cover for protecting the display device 1.

In FIG. 1, a display module, which is a main component of the display device 1, is illustrated. In one or more embodiments, the display device 1 (or an electronic device including a display module) may further include an additional component. For example, the display device 1 may further include a housing or a casing that accommodates the display module of FIG. 1.

In one or more embodiments, the display device 1 may be a light emitting display device such as an organic light emitting display using an organic light emitting diode, a quantum dot light emitting display including a quantum dot light emitting layer, an inorganic light emitting display including an inorganic semiconductor, and an ultra-small light emitting display using an ultra-small light emitting diode (for example, a micro light emitting diode (micro LED) or a nano light emitting diode (nano LED)). Hereinafter, as an example of the display device 1 to which embodiments may be applied, a micro or nano light emitting display including a micro or nano light emitting diode will be disclosed. However, the present disclosure is not limited thereto. For example, the type of light emitting element included in the display device 1 is not limited to an ultra-small light emitting diode, and the display device 1 may include light emitting elements of other types and/or sizes.

The display device 1 may include a display panel 100, a display driving circuit 250, a circuit board 300, and a power supply unit 500 (also referred to as "power supply circuit").

The display panel 100 may, in a plan view, may be formed in a rectangular shape having short sides in a first direction DR1 and long sides in a second direction DR2 crossing the first direction DR1. The corner where the sides in the first direction DR1 and the sides in the second direction DR2 meet may be formed in a rounded or angled shape. The planar shape of the display panel 100 is not limited to the rectangular shape, and may be formed in another polygonal shape, a circular shape or an elliptical shape. The display panel 100 may be formed to be substantially flat, but is not limited thereto. The display panel 100 may be formed to be rigid as a whole, or may be formed to be flexible so that it can be curved, warped, bent, folded, and/or rolled in at least one part.

The display panel 100 may include a main region MA and a sub-region SBA.

The main region MA may include a display area DA for displaying an image and a non-display area NDA that is a peripheral area of the display area DA. The display area DA may include pixels for displaying an image. Each of the pixels may include a plurality of sub-pixels. For example, each of the pixels may include a first sub-pixel that emits light of a first color, a second sub-pixel that emits light of a second color, and a third sub-pixel that emits light of a third color, but the present disclosure is not limited thereto.

The sub-region SBA may protrude from one side of the main region MA in the second direction DR2. Although it is shown as an example in FIG. 1 that the sub-region SBA is unfolded, the sub-region SBA may be bent and, in this case, arranged on the bottom surface of the display panel 100. In the case where the sub-region SBA is bent, it may overlap the main region MA in a third direction DR3 that is a thickness direction of the display panel 100. The display driving circuit 250 may be arranged in the sub-region SBA.

The display driving circuit 250 may generate signals and voltages for driving the display panel 100. The display driving circuit 250 may be formed as an integrated circuit (IC) and attached onto the display panel 100 by a chip on glass (COG) method, a chip on plastic (COP) method, or an ultrasonic bonding method, but the present disclosure is not limited thereto. For example, the display driving circuit 250 may be attached onto the circuit board 300 by a chip on film (COF) method.

The circuit board 300 may be attached to one end of the sub-region SBA. In the case where the sub-region SBA is omitted, the circuit board 300 may be attached to one end (for example, one end of the non-display area NDA of the main region MA. Thus, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film.

The power supply unit 500 may generate a plurality of panel driving voltages according to a power voltage supplied from the outside. The power supply unit 500 may be formed as an integrated circuit (IC) and attached to the circuit board 300 by a COF method.

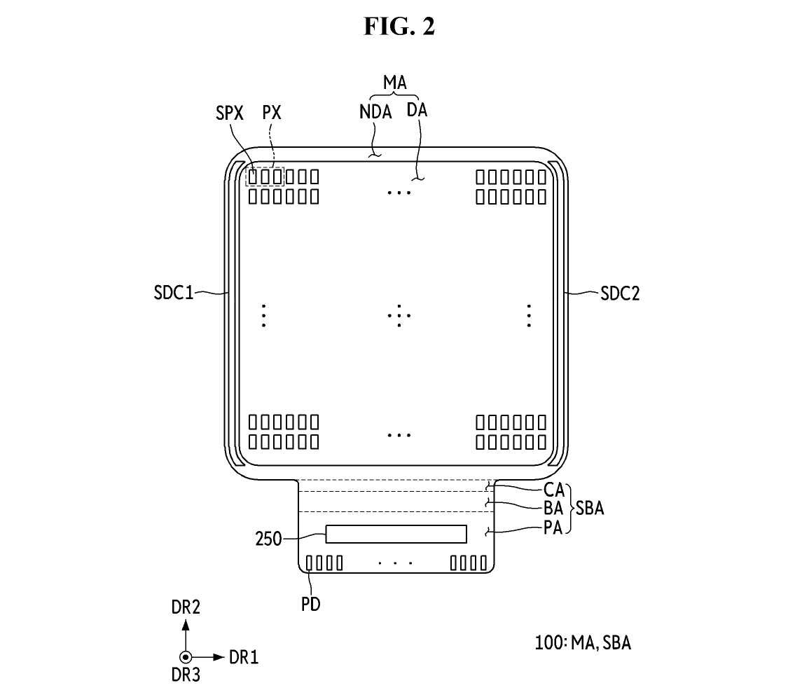

FIG. 2 is a layout view illustrating a display device according to one or more embodiments. It is shown as an example in FIG. 2 that the sub-region SBA is unfolded without being bent.

Referring to FIG. 2, the display panel 100 may include the main region MA and the sub-region SBA.

The main region MA may include the display area DA for displaying an image and the non-display area NDA that is a peripheral area of the display area DA. The display area DA may occupy most of the main region MA. The display area DA may be located at the center of the main region MA.

The display area DA may include pixels PX for displaying an image, and each of the pixels PX may include a plurality of sub-pixels SPX. The pixel PX may be defined as a minimum unit sub-pixel group capable of expressing a white gray level.

The non-display area NDA may be located adjacent to the display area DA. The non-display area NDA may be an area outside the display area DA. The non-display area NDA may be around (may surround) the display area DA. The non-display area NDA may be an edge area of the display panel 100.

A first scan driver SDC1 and a second scan driver SDC2 may be located in the non-display area NDA. The first scan driver SDC1 may be located at one side (for example, left side) of the display panel 100, and the second scan driver SDC2 may be located at the other side (for example, right side) of the display panel 100, but the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive scan control signals inputted from the display driving circuit 250, generate scan signals in response to the scan control signals, and output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be foldable to be located under the display panel 100. In this case, the sub-region SBA may overlap the main region MA in the third direction DR3.

The sub-region SBA may include a connection area CA, a pad area PA, and a bending area BA.

The connection area CA is an area protruding from one side of the main region MA in the second direction DR2. One side of the connection area CA may be in contact with the non-display area NDA of the main region MA, and the other side of the connection area CA may be in contact with the bending area BA.

The pad area PA is an area on which pads PD and the display driving circuit 250 are arranged. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is an area being bent. When the bending area BA is bent, the pad area PA may be located under the connection area CA and the main region MA. The bending area BA may be located between the connection area CA and the pad area PA. One side of the bending area BA may be in contact with the connection area CA, and the other side of the bending area BA may be in contact with the pad area PA.

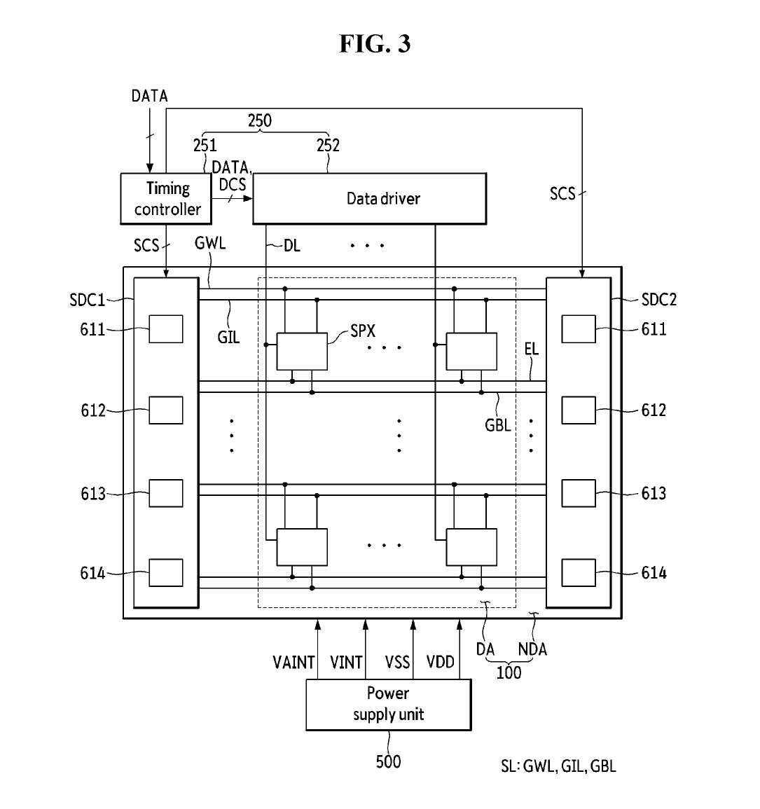

FIG. 3 is a block diagram illustrating a display device according to one or more embodiments.

Referring to FIG. 3 in addition to FIGS. 1 and 2, the display area DA may include pixels PX, scan lines SL, emission control lines EL, and data lines DL.

The pixels PX may be arranged in a matrix form or the like. For example, the pixels PX may be arranged in a matrix form along the first direction DR1 (see FIG. 2) and the second direction DR2 (see FIG. 2), but the present disclosure is not limited thereto. For example, the pixels PX may be arranged along rows and columns of a matrix along the first direction DR1 and the second direction DR2. The scan lines SL and the emission control lines EL may extend in the first direction DR1 and may be arranged along the second direction DR2. The data lines DL may extend in the second direction DR2 and may be arranged along the first direction DR1. In one or more embodiments, the scan lines SL may include write scan lines GWL, initialization scan lines GIL, and bias scan lines GBL.

Each of the plurality of sub-pixels SPX included in each of the pixels PX may be connected to one write scan line GWL from among the write scan lines GWL, one initialization scan line GIL from among the initialization scan lines GIL, one bias scan line GBL from among the bias scan lines GBL, one emission control line EL from among the emission control lines EL, and one data line DL from among the data lines DL. In describing the embodiments, the term "connection" may include direct connection or indirect connection, and may include the meaning of electrical and/or physical connection. Each of the plurality of sub-pixels SPX may receive the data voltage of the data line DL according to the write scan signal of the write scan line GWL, and may cause a light emitting element to emit light according to the data voltage.

The non-display area NDA includes the first scan driver SDC1, the second scan driver SDC2, and the display driving circuit 250.

Each of the first scan driver SDC1 and the second scan driver SDC2 may include a write scan signal output unit 611, an initialization scan signal output unit 612, a bias scan signal output unit 613, and an emission control signal output unit 614. Each of the write scan signal output unit 611, the initialization scan signal output unit 612, the bias scan signal output unit 613, and the emission control signal output unit 614 may receive a scan timing control signal SCS from a timing controller 251 (also referred to as "timing control circuit").

The write scan signal output unit 611 may generate write scan signals according to the scan timing control signal SCS of the timing controller 251 and output them sequentially to the write scan lines GWL.

The initialization scan signal output unit 612 may generate initialization scan signals in response to the scan timing control signal SCS and sequentially output them to the initialization scan lines GIL.

The bias scan signal output unit 613 may generate bias scan signals according to the scan timing control signal SCS and output them sequentially to the bias scan lines GBL.

The emission control signal output unit 614 may generate emission control signals according to the scan timing control signal SCS and sequentially output them to the emission control lines EL.

The display driving circuit 250 includes the timing controller 251 and a data driver 252 (also referred to as "data driving circuit").

The data driver 252 may receive the digital video data DATA and the data timing control signal DCS from the timing controller 251. The data driver 252 converts the digital video data DATA into analog data voltages in response to the data timing control signal DCS, and outputs them to the data lines DL. In this case, the sub-pixels SPX may be selected by the write scan signal of the first scan driver SDC1 and the second scan driver SDC2, and data voltages may be supplied to the selected sub-pixels SPX.

The timing controller 251 may receive digital video data DATA and timing signals from the outside. The timing controller 251 may generate the scan timing control signal SCS and the data timing control signal DCS for controlling the display panel 100 in response to the timing signals. The timing control circuit 400 may output the scan timing control signal SCS to the first scan driver SDC1 and the second scan driver SDC2. The timing controller 251 may output the digital video data DATA and the data timing control signal DCS to the data driver 252.

The power supply unit 500 may generate a plurality of panel driving voltages according to a power voltage supplied from the outside. For example, the power supply unit 500 may generate a first driving voltage VDD, a second driving voltage VSS, a third driving voltage VINT, and a fourth driving voltage VAINT and supply them to the display panel 100.

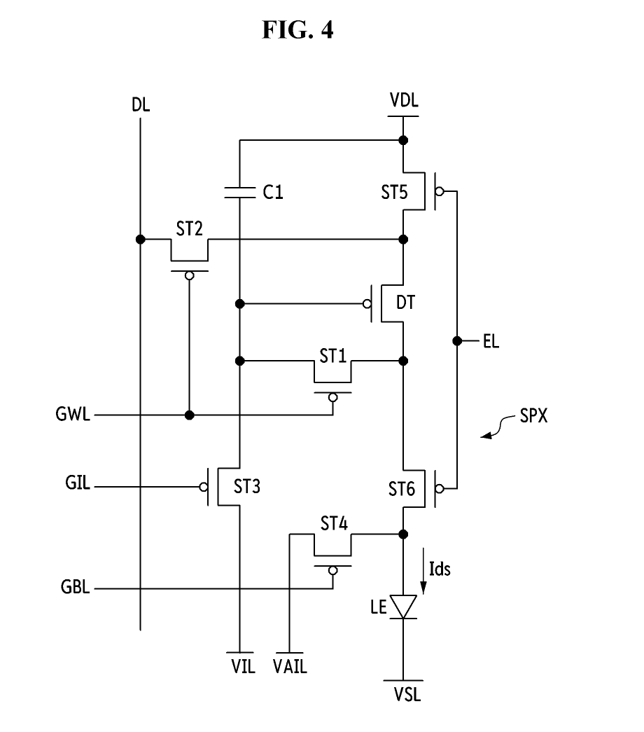

FIG. 4 is an equivalent circuit diagram illustrating a sub-pixel according to one or more embodiments.

Referring to FIG. 4 in addition to FIG. 3, the sub-pixel SPX according to one or more embodiments may be connected to the scan lines GWL, GIL, and GBL, the emission control line EL, and the data line DL. For example, the sub-pixel SPX may be connected to the write scan line GWL, the initialization scan line GIL, the bias scan line GBL, the emission control line EL, and the data line DL.

The sub-pixel SPX according to one or more embodiments may include a driving transistor DT, switch elements, a capacitor C1, and a light emitting element LE. In one or more embodiments, the switch elements may include first to sixth transistors ST1, ST2, ST3, ST4, ST5, and ST6.

The driving transistor DT includes a gate electrode, a first electrode, and a second electrode. The driving transistor DT controls the driving current Ids flowing between the first electrode and the second electrode according to a data voltage applied to the gate electrode of the driving transistor DT.

The light emitting element LE may be electrically connected to the driving transistor DT, and may emit light with a luminance corresponding to the driving current Ids. In one or more embodiments, the anode electrode of the light emitting element LE may be connected to the first electrode of the fourth transistor ST4 and the second electrode of the sixth transistor ST6, and the cathode electrode thereof may be connected to a second power line VSL to which a second driving voltage is applied. In one or more embodiments, the light emitting element LE may be a micro light emitting diode.

The capacitor C1 is formed between the gate electrode of the driving transistor DT and a first power line VDL to which a first driving voltage is applied. The first driving voltage may be the voltage having a level higher than that of the second driving voltage. One electrode of the capacitor C1 may be connected to the gate electrode of the driving transistor DT, and the other electrode thereof may be connected to the first power line VDL.

In one or more embodiments, as shown in FIG. 4, the first to sixth transistors ST1 to ST6, and the driving transistor DT may all be formed as p-type metal oxide semiconductor field effect transistors (MOSFETs) as shown in FIG. 4. The active layer of each of the driving transistor DT and the first to sixth transistors ST1 to ST6 may include polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1 to ST6 are formed as p-type MOSFETs, they may be turned on when a scan signal and an emission control signal of a gate low voltage are applied to the initialization scan line GIL, and the write scan line GWL, the bias scan line GBL, and the emission line EL. One electrode of the third transistor ST3 may be connected to a first initialization voltage line VIL to which the third driving voltage VINT (see FIG. 3) is applied, and one electrode of the fourth transistor ST4 may be connected to a second initialization voltage line VAIL to which the fourth driving voltage VAINT (see FIG. 3) is applied. The third driving voltage VINT (see FIG. 3) and the fourth driving voltage VAINT (see FIG. 3) may be different voltages. Further, the third driving voltage VINT (see FIG. 3) and the fourth driving voltage VAINT (see FIG. 3) may be voltages having a level lower than that of the first driving voltage VDD and having a level higher than that of the second driving voltage VSS.

Alternatively, the driving transistor DT, the second transistor ST2, the fourth transistor ST4, the fifth transistor ST5, and the sixth transistor ST6 may be configured as p-type metal oxide semiconductor field effect transistors (MOSFETs), and the first transistor ST1 and the third transistor ST3 may be configured as n-type MOSFETs. In this case, an active layer of each of the driving transistor DT, the second transistor ST2, the fourth transistor ST4, the fifth transistor ST5 and the sixth transistor ST6 configured as the p-type MOSFETs may include polysilicon, whereas an active layer of each of the first transistor ST1 and the third transistor ST3 configured as the n-type MOSFETs may include an oxide semiconductor. In addition, because the first transistor ST1 and the third transistor ST3 are formed as n-type MOSFETs, the first transistor ST1 may be turned on when the scan signal of a gate high voltage is applied, and the third transistor ST3 may be turned on when the initialization scan signal of a gate high voltage is applied. In contrast, because the second transistor ST2, the fourth transistor ST4, the fifth transistor ST5, and the sixth transistor ST6 are configured as the p-type MOSFETs, they may be turned on when an emission control signal and a scan signal of a gate low voltage are applied.

Alternatively, when the fourth transistor ST4 is formed as an n-type MOSFET, and the other transistors DT, ST1, ST2, ST3, ST5, and ST6 are formed as p- type MOSFETs, the active layer of the fourth transistor ST4 may include an oxide semiconductor, and the active layer of each of the other transistors DT, ST1, ST2, ST3, ST5, and ST6 may include polysilicon. Further, the fourth transistor ST4 may be turned on when a scan signal of a gate high voltage is applied, whereas the other transistors DT, ST1, ST2, ST3, ST5, and ST6 may be turned on when an emission control signal and a scan signal of a gate low voltage are applied.

Alternatively, the first to sixth transistors ST1, ST2, ST3, ST4, ST5, and ST6, and the driving transistor DT may all be formed as n-type MOSFETs. In this case, the active layer of each of the driving transistor DT and the first to sixth transistors ST1, ST2, ST3, ST4, ST5, and ST6 may include an oxide semiconductor, and may be turned on when an emission control signal and a scan signal of a gate high voltage are applied.

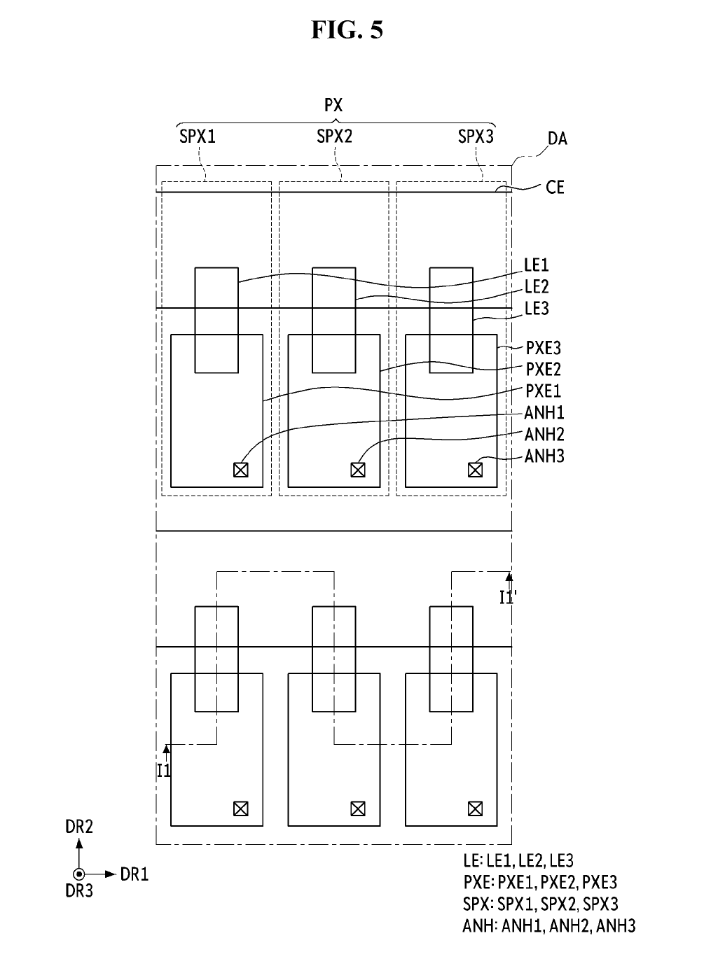

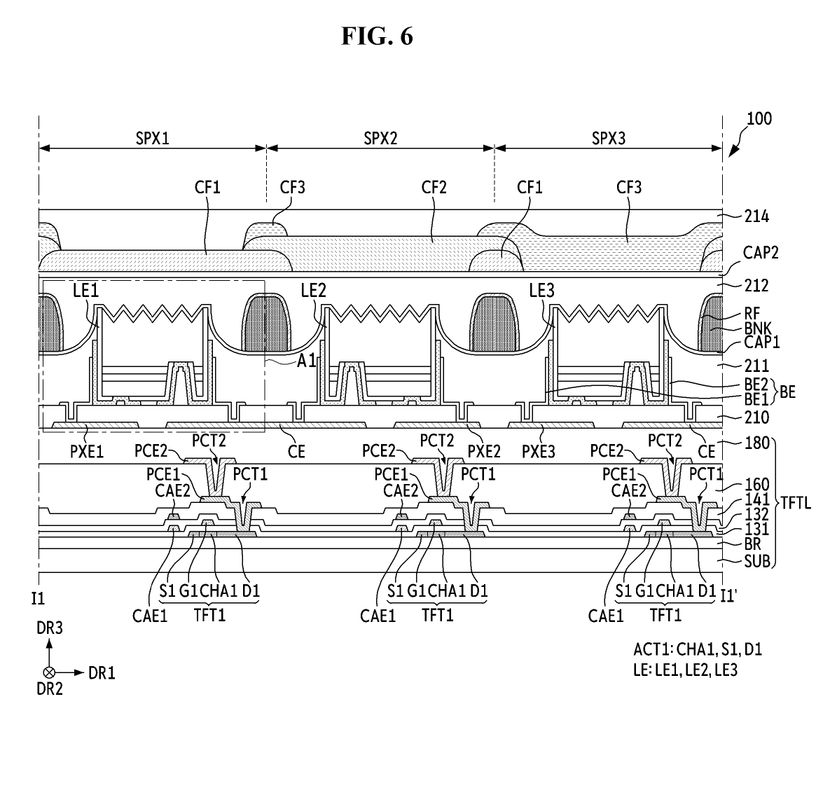

FIG. 5 is a plan view illustrating a display area of a display panel according to one or more embodiments. For example, FIG. 5 shows a part of the display area DA including two pixels PX sequentially arranged along the second direction DR2. FIG. 5 shows an embodiment of a layout structure of a light emitting element layer including light emitting elements LE of the sub-pixels SPX from among elements included in the display panel 100 (see FIGS. 1 – 3). The display panel 100 may further include a backplane layer (for example, a thin film transistor layer TFTL of FIG. 6) including circuit elements (for example, transistors and a capacitor C1 of FIG. 4) of each of the sub-pixels SPX.

Referring to FIG. 5, each of the sub-pixels SPX may include the pixel electrode PXE, and the light emitting element LE located on the pixel electrode PXE. In one or more embodiments, when the light emitting element LE is a flip-chip type light emitting element (e.g., a flip-chip micro LED), each of the sub-pixels SPX may further include the common electrode CE located on one surface (for example, a bottom surface) of the light emitting element LE together with the pixel electrode PXE.

In one or more embodiments, the sub-pixels SPX of each pixel PX may be arranged along the first direction DR1 and may share one common electrode CE. For example, the common electrode CE may extend in the first direction DR1 in each pixel row (or horizontal line) of the display area DA, and the sub-pixels SPX of the pixels PX located on the corresponding pixel row may share one common electrode CE. The common electrode CE may be electrically connected to the second power line VSL (see FIG. 4) to which the second driving voltage VSS (see FIG. 3) is applied, inside the display area DA and/or in the non-display area NDA (see FIGS. 1 – 3).

However, the shape or connection structure of the common electrode CE is not limited thereto. For example, the sub-pixels SPX of the pixel PX according to one or more embodiments may include the respective common electrodes CE separated from each other. In this case, the common electrode CE may be formed separately for each sub-pixel SPX and may be electrically connected to the second power line VSL (see FIG. 4) through each contact hole and/or connection pattern and/or the like.

In one or more embodiments, the sub-pixels SPX for emitting light of the same type and/or color from among the sub-pixels SPX of the display area DA may be arranged sequentially or continuously along the second direction DR2. For example, first sub-pixels SPX1 of the pixels PX included in each pixel column extending in the second direction DR2 in the display area DA may be arranged sequentially or continuously along the second direction DR2. In addition, the second sub-pixels SPX2 of the pixels PX included in each pixel column may be arranged sequentially or continuously along the second direction DR2, and the third sub-pixels SPX3 of the pixels PX included in each pixel column may be arranged sequentially or continuously along the second direction DR2. However, the arrangement form of the pixels PX and/or the sub-pixels SPX may vary depending on embodiments.

The first sub-pixel SPX1 may include a first pixel electrode PXE1 and the common electrode CE (or a part of the common electrode CE) spaced (e.g., spaced apart) from each other, and a first light emitting element LE1 located on the first pixel electrode PXE1 and the common electrode CE. The first pixel electrode PXE1 may refer to the pixel electrode PXE of the first sub-pixel SPX1, and the first light emitting element LE1 may refer to the light emitting element LE of the first sub-pixel SPX1. The first light emitting element LE1 may be electrically connected between the first pixel electrode PXE1 and the common electrode CE.

The second sub-pixel SPX2 may include a second pixel electrode PXE2 and the common electrode CE spaced (e.g., spaced apart) from each other, and a second light emitting element LE2 located on the second pixel electrode PXE2 and the common electrode CE. The second pixel electrode PXE2 may refer to the pixel electrode PXE of the second sub-pixel SPX2, and the second light emitting element LE2 may refer to the light emitting element LE of the second sub-pixel SPX2. The second light emitting element LE2 may be electrically connected between the second pixel electrode PXE2 and the common electrode CE.

The third sub-pixel SPX3 may include a third pixel electrode PXE3 and the common electrode CE spaced (e.g., spaced apart) from each other, and a third light emitting element LE3 located on the third pixel electrode PXE3 and the common electrode CE. The third pixel electrode PXE3 may refer to the pixel electrode PXE of the third sub-pixel SPX3, and the third light emitting element LE3 may refer to the light emitting element LE of the third sub-pixel SPX3. The third light emitting element LE3 may be electrically connected between the third pixel electrode PXE3 and the common electrode CE.

In one or more embodiments, the first pixel electrode PXE1, the second pixel electrode PXE2, and the third pixel electrode PXE3 of each pixel PX may be sequentially arranged along the first direction DR1, and may be spaced (e.g., spaced apart) from the common electrode CE in the second direction DR2. The first pixel electrode PXE1, the second pixel electrode PXE2, and the third pixel electrode PXE3 may face different parts of the common electrode CE in the second direction DR2.

The pixel electrode PXE and circuit elements of each of the sub-pixels SPX may be electrically connected to each other through at least one contact hole ANH and/or a connection pattern and/or the like. For example, the first pixel electrode PXE1 of the first sub-pixel SPX1 may be electrically connected to at least one circuit element (e.g., the fourth and sixth transistors ST4 and ST6 of FIG. 4) included in the first sub-pixel SPX1 through a first anode contact hole ANH1 and/or at least one connection pattern. Similarly, the second pixel electrode PXE2 of the second sub-pixel SPX2 may be electrically connected to at least one circuit element included in the second sub-pixel SPX2 through a second anode contact hole ANH2 and/or at least one connection pattern, and the third pixel electrode PXE3 of the third sub-pixel SPX3 may be electrically connected to at least one circuit element included in the third sub-pixel SPX3 through a third anode contact hole ANH3 and/or at least one connection pattern.

The light emitting elements LE may be located between the respective pixel electrodes PXE and the common electrode CE. For example, the first light emitting element LE1 may be located on the first pixel electrode PXE1 and the common electrode CE, and a part of the first light emitting element LE1 may overlap the first pixel electrode PXE1 and another part of the first light emitting element LE1 may overlap the common electrode CE. The second light emitting element LE2 may be located on the second pixel electrode PXE2 and the common electrode CE, and a part of the second light emitting element LE2 may overlap the second pixel electrode PXE2 and another part of the second light emitting element LE2 may overlap the common electrode CE. The third light emitting element LE3 may be located on the third pixel electrode PXE3 and the common electrode CE, and a part of the third light emitting element LE3 may overlap the third pixel electrode PXE3 and another part of the third light emitting element LE3 may overlap the common electrode CE.

Each of the light emitting elements LE may emit light of a specific color (for example, red light, green light, blue light, or white light). In one or more embodiments, the first light emitting element LE1, the second light emitting element LE2, and the third light emitting element LE3 may emit light of different colors. For example, the first light emitting element LE1, the second light emitting element LE2, and the third light emitting element LE3 may emit light of a first color (for example, red light), light of a second color (for example, green light), and light of a third color (for example, blue light), respectively.

In one or more embodiments, the first light emitting element LE1, the second light emitting element LE2, and the third light emitting element LE3 may emit light of the same color. In this case, a light conversion layer (e.g., a light conversion layer including wavelength conversion particles) may be located on at least one light emitting element LE from among the first sub-pixel SPX1, the second sub-pixel SPX2, and the third sub-pixel SPX3 to convert light emitted from the light emitting element LE of the corresponding sub-pixel SPX into light corresponding to the emission color of the corresponding sub-pixel SPX.

FIG. 6 is a cross-sectional view illustrating a display area of a display panel according to one or more embodiments. For example, FIG. 6 illustrates one embodiment of a cross-section of the pixel PX corresponding to the line I1-I1' of FIG. 5.

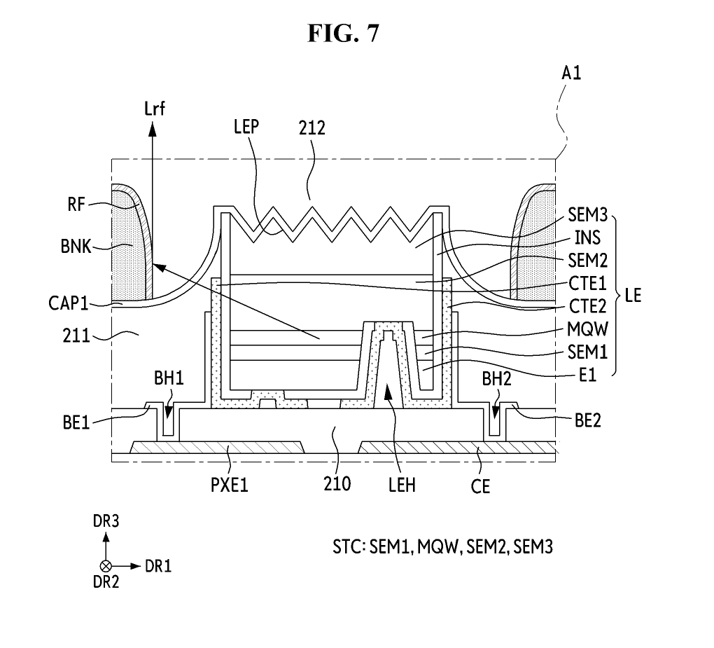

FIG. 7 is a cross-sectional view showing an area A1 of FIG. 6 in detail. For example, FIG. 7 illustrates the light emitting element LE according to one or more embodiments, for example, the first light emitting element LE1 located in area A1 of FIG. 6 in detail. In one or more embodiments, the first light emitting element LE1, the second light emitting element LE2, and the third light emitting element LE3 may have substantially the same cross-sectional structure.

Referring to FIGS. 6 and 7 in addition to FIG. 5, the substrate SUB may include an insulating material such as glass and/or polymer resin. When the substrate SUB includes polymer resin, it may be a flexible substrate that can be stretched. The polymer resin may include acryl resin, epoxy resin, phenolic resin, polyamide resin, and/or polyimide resin.

The barrier layer BR may be located on the substrate SUB. The barrier layer BR is a film for protecting transistors of the thin film transistor layer TFTL and the light emitting elements LE arranged on the thin film transistor layer TFTL from moisture permeating through the substrate SUB which is susceptible to moisture permeation. The barrier layer BR may include a plurality of inorganic films that are alternately stacked.

The thin film transistor TFT1 may be located on the barrier layer BR. In one or more embodiments, the first thin film transistor TFT1 may be one of the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be located on the barrier layer BR. The first active layer ACT1 of the thin film transistor TFT1 may include polycrystalline silicon, monocrystalline silicon, low-temperature polycrystalline silicon, and/or amorphous silicon. Alternatively, the first active layer ACT1 of the thin film transistor TFT1 may include an oxide semiconductor (for example, indium gallium zinc oxide (IGZO), indium gallium zinc tin oxide (IGZTO), and/or indium gallium tin oxide (IGTO)).

The first active layer ACT1 may include a first channel region CHA1, a first source region S1, and a first drain region D1. The first channel region CHA1 may overlap the first gate electrode G1 in the third direction DR3. The first source region S1 may be located on one side of the first channel region CHA1, and the first drain region D1 may be located on the other side of the first channel region CHA1. At least a part of the first source region S1 and the first drain region D1 may not overlap the first gate electrode G1 in the third direction DR3. The conductivity (for example, carrier concentration) of the first source region S1 and the first drain region D1 may be higher than the conductivity of the first channel region CHA1.

A first gate insulating layer 131 may be located on a first channel region CHA1, a first source region S1, and a first drain region D1 of the thin film transistor TFT1 and on the barrier layer BR.

A first gate metal layer may be located on the first gate insulating layer 131. The first gate metal layer may include the first gate electrode G1 of the thin film transistor TFT1 and the first capacitor electrode CAE1. The first gate electrode G1 may overlap the first active layer ACT1 in the third direction DR3. Although it is illustrated in FIG. 6 that the first gate electrode G1 and the first capacitor electrode CAE1 are spaced (e.g., spaced apart) from each other, the first gate electrode G1 and the first capacitor electrode CAE1 may be electrically and/or physically connected to each other when the thin film transistor TFT1 is the driving transistor DT of FIG. 4. For example, the first capacitor electrode CAE1 may be formed integrally with the gate electrode of the driving transistor DT of FIG. 4, and may be formed separately from the gate electrodes of the first to sixth transistors ST1, ST2, ST3, ST4, ST5, and ST6 of FIG. 4.

A second gate insulating layer 132 may be located on the first gate electrode G1 of the thin film transistor TFT1, the first capacitor electrode CAE1, and on the first gate insulating layer 131.

A second gate metal layer may be located on the second gate insulating layer 132. The second gate metal layer may include a second capacitor electrode CAE2. The second capacitor electrode CAE2 may overlap the first capacitor electrode CAE1 in the third direction DR3. The first capacitor C1 (see FIG. 4) may be formed by the first capacitor electrode CAE1, the second capacitor electrode CAE2, and the second gate insulating layer 132.

An interlayer insulating layer 141 may be located on the second capacitor electrode CAE2 and on the second gate insulating layer 132.

A first data metal layer may be located on the interlayer insulating layer 141. The first data metal layer may include a first source connection electrode PCE1. The first source connection electrode PCE1 may be connected to the first drain region D1 of the first active layer ACT1 through a first source contact hole PCT1 penetrating the first gate insulating layer 131, the second gate insulating layer 132, and the interlayer insulating layer 141.

A first planarization layer 160 for flattening a stepped portion formed by the thin film transistor TFT1 may be located on the first source connection electrode PCE1 and on the interlayer insulating layer 141.

A second data metal layer may be located on the first planarization layer 160. The second data metal layer may include a second source connection electrode PCE2. The second source connection electrode PCE2 may be connected to the first source connection electrode PCE1 through a second source contact hole PCT2 penetrating the first planarization layer 160.

A second planarization layer 180 may be located on the second source connection electrode PCE2 and on the first planarization layer 160.

The barrier layer BR, the first gate insulating layer 131, the second gate insulating layer 132, and the interlayer insulating layer 141 may be formed as at least one inorganic insulating layer including an inorganic insulating material (for example, silicon nitride (SiNₓ), silicon oxynitride (SiON), silicon oxide (SiOₓ), titanium oxide (TiOₓ), and/or aluminum oxide (AlOₓ)). Each of the barrier layer BR, the first gate insulating layer 131, the second gate insulating layer 132, and the interlayer insulating layer 141 may be formed in a single-layer or multi-layer structure.

The first gate metal layer, the second gate metal layer, the first data metal layer, and the second data metal layer may include a conductive material (for example, molybdenum (Mo), aluminum (Al), chromium (Cr), gold (Au), titanium (Ti), nickel (Ni), neodymium (Nd), and/or copper (Cu), and/or an alloy thereof). Each of the first gate metal layer, the second gate metal layer, the first data metal layer, and the second data metal layer may be formed in a single-layer or multi-layer structure.

The first planarization layer 160 and the second planarization layer 180 may include at least one organic insulating layer containing an organic insulating material (e.g., acryl resin, epoxy resin, phenolic resin, polyamide resin, polyimide resin, and/or the like). Each of the first planarization layer 160 and the second planarization layer 180 may be formed in a single-layer or multi-layer structure.

A light emitting element layer may be located on the second planarization layer 180. The light emitting element layer may include the pixel electrodes PXE, the common electrode CE, and the light emitting elements LE. The light emitting element layer may further include first and second organic layers 210 and 211, a light transmitting layer 212 (or a third organic layer), first and second capping layers CAP1 and CAP2, a bank BNK (or a light blocking layer), a reflective film RF, and/or the like located around the light emitting elements LE.

The pixel electrode layer may be located on the second planarization layer 180. The pixel electrode layer may include the pixel electrodes PXE (e.g., the first pixel electrode PXE1, the second pixel electrode PXE2, and the third pixel electrode PXE3) of the sub-pixels SPX. In one or more embodiments, the light emitting element LE of the sub-pixel SPX may be a flip-type micro LED (e.g., a flip-chip micro LED) in which first and second contact electrodes CTE1 and CTE2 are located on one surface (e.g., the bottom surface) of the light emitting element LE. In this case, the pixel electrode layer may further include the common electrode CE.

Each of the pixel electrodes PXE may be electrically connected to the second source connection electrode PCE2 of each of the sub-pixels SPX through the contact hole ANH (e.g., the first anode contact hole ANH1, the second anode contact hole ANH2, or the third anode contact hole ANH3 of FIG. 5) penetrating the second planarization layer 180. Each of the pixel electrodes PXE may be electrically connected to the first source region S1 or the first drain region D1 of the thin film transistor TFT1 through the first source connection electrode PCE1 and the second source connection electrode PCE2.

The pixel electrode layer may include a conductive material (e.g., molybdenum (Mo), aluminum (Al), chromium (Cr), gold (Au), titanium (Ti), nickel (Ni), neodymium (Nd) and/or copper (Cu), and/or an alloy thereof), and may be formed as a single layer or multiple layers. For example, the pixel electrodes PXE and the common electrode CE may each be formed in a single-layer or multi-layer conductive pattern including at least one conductive material. The pixel electrodes PXE and the common electrode CE may be formed concurrently (e.g., simultaneously), and thus may have the same conductive material and cross-sectional structure.

In one or more embodiments, the pixel electrode layer may include a reflective layer including a metal with high reflectivity. For example, each of the pixel electrodes PXE and the common electrode CE may include a reflective layer. Accordingly, the luminance and light efficiency of the sub-pixels SPX may be improved by reflecting the downward light of the light emitting elements LE.

In one or more embodiments, the first organic layer 210 may be located on the pixel electrodes PXE and the common electrode CE. For example, the first organic layer 210 may be located between the pixel electrode layer and the light emitting element LE, and may cover a portion of each of the pixel electrodes PXE and the common electrode CE. The first organic layer 210 may not cover another portion of each of the pixel electrodes PXE and the common electrode CE. For example, the first organic layer 210 may be removed or etched at a portion in which a first connection hole BH1 and a second connection hole BH2 are formed, to expose another portion of each of the pixel electrodes PXE and the common electrode CE.

The first organic layer 210 serves to temporarily fix or adhere the plurality of light emitting elements LE in order to prevent them from tilting or falling during the process of transferring the plurality of light emitting elements LE to the display panel 100. For example, the first organic layer 210 may be a film for temporarily adhering the light emitting elements LE onto the pixel electrodes PXE and the common electrode CE. To facilitate temporary adhesion, the thickness of the first organic layer 210 may be greater than the thickness of each of the pixel electrodes PXE and the common electrode CE, and may be greater than the thickness of each of the first and second contact electrodes CTE1 and CTE2 of the light emitting elements LE.

FIG. 6 illustrates a structure in which the first organic layer 210 is formed entirely in the display area DA, but the present disclosure is not limited thereto. For example, the first organic layer 210 may be located only at a portion of a sub-pixel area, including a portion of the pixel electrode PXE and the common electrode CE of each of the sub-pixels SPX.

The first organic layer 210 may include an organic insulating material. For example, the first organic layer 210 may be formed as a photosensitive organic film including a photoresist. Alternatively, the first organic layer 210 may be formed as an organic film including acryl resin, epoxy resin, phenolic resin, polyamide resin, polyimide resin, and/or the like.

The light emitting elements LE may be located on the first organic layer 210. Each of the light emitting elements LE may include an inorganic material such as gallium nitride (GaN). In one or more embodiments, each of the light emitting elements LE may have a length of several tens to several hundreds of µm in each of the first direction DR1, the second direction DR2, and the third direction DR3. For example, in each of the light emitting elements LE, each of the length in the first direction DR1, the length in the second direction DR2, and the length in the third direction DR3 may be 100 μm or less.

The light emitting elements LE may be formed by growing on a semiconductor substrate such as a silicon substrate or sapphire substrate. The light emitting elements LE may be transferred directly from the semiconductor substrate onto the pixel electrodes PXE and the common electrode CE. Alternatively, the light emitting elements LE may be transferred onto the common electrode CE and the pixel electrodes PXE through an electrostatic method using an electrostatic head or a stamping method using an elastic polymer material such as PDMS and/or silicon as a transfer substrate.

In one or more embodiments, as illustrated in FIG. 7, the light emitting element LE may include a conductive layer E1, a semiconductor stack STC, the first and second contact electrodes CTE1 and CTE2, and a protective film INS. The semiconductor stack STC may include the first semiconductor layer SEM1, the active layer (also referred to as “light emitting layer”) MQW, and the second semiconductor layer SEM2 that are sequentially arranged or stacked along the third direction DR3. In one or more embodiments, the semiconductor stack STC may further include a third semiconductor layer SEM3 on the second semiconductor layer SEM2.

The conductive layer E1 may be located on the bottom surface of the first semiconductor layer SEM1. Although it is illustrated in FIG. 7 that the conductive layer E1 covers the entire bottom surface of the first semiconductor layer SEM1, the present disclosure is not limited thereto. For example, the conductive layer E1 may be located only on a portion of the bottom surface of the first semiconductor layer SEM1. The conductive layer E1 may include a conductive material (e.g., molybdenum (Mo), aluminum (Al), chromium (Cr), gold (Au), titanium (Ti), nickel (Ni), neodymium (Nd), and/or copper (Cu), and/or a transparent conductive material such as metal oxide).

The first semiconductor layer SEM1 may be located on the conductive layer E1. The first semiconductor layer SEM1 may be formed as a semiconductor material layer doped with a first conductivity type dopant such as magnesium (Mg), zinc (Zn), calcium (Ca), strontium (Sr), or barium (Ba), for example, gallium nitride (GaN).

The active layer MQW may be located on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN). The active layer MQW may emit light by coupling of electron-hole pairs according to an electrical signal applied through the first semiconductor layer SEM1 and the second semiconductor layer SEM2.

The active layer MQW may have a single or multiple quantum well structure. When the active layer MQW is formed in a multiple quantum well structure, the active layer MQW may include well layers and barrier layers that are alternately stacked. In one or more embodiments, each well layer may include InGaN, and each barrier layer may include GaN and/or AlGaN, but are not limited thereto. Alternatively, the active layer MQW may have a structure in which a semiconductor material having large band gap energy and a semiconductor material having small band gap energy are alternately stacked, and may include other Group III to Group V semiconductor materials according to the wavelength band of the emitted light.

When the active layer MQW includes indium gallium nitride (InGaN), the color of emitted light may vary depending on the content of indium (In). For example, as the content of indium (In) increases, the wavelength band of the light emitted by the active layer may shift to the red wavelength band, and as the content of indium (In) decreases, the wavelength band of the light emitted by the active layer may shift to the blue wavelength band. For example, the content of indium (In) of the active layer MQW included in the second light emitting element LE2 may be higher than the content of indium (In) of the active layer MQW included in the first light emitting element LE1 and may be less than the content of indium (In) of the active layer MQW included in the third light emitting element LE3.

The second semiconductor layer SEM2 may be located on the active layer MQW. The second semiconductor layer SEM2 may be a semiconductor material layer, for example, gallium nitride (GaN), doped with a second conductivity type dopant such as silicon (Si), germanium (Ge), and/or tin (Sn).

The third semiconductor layer SEM3 may be located on the second semiconductor layer SEM2. The third semiconductor layer SEM3, which is a semiconductor material layer having an n-type dopant concentration lower than a selected threshold value, may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type dopant concentration lower than the selected threshold value. The third semiconductor layer SEM3 may be omitted.

An electron blocking layer may be located between the first semiconductor layer SEM1 and the active layer MQW. The electron blocking layer may be a layer for suppressing or preventing too many electrons from flowing into the active layer MQW. For example, the electron blocking layer may be AlGaN and/or p-AlGaN doped with p-type Mg. The electron blocking layer may be omitted.

A superlattice layer may be located between the active layer MQW and the second semiconductor layer SEM2. The superlattice layer may be a layer for relieving stress between the second semiconductor layer SEM2 and the active layer MQW. For example, the superlattice layer may include InGaN and/or GaN. The superlattice layer may be omitted.

The protective film INS may be around (e.g., may surround) the side surface (e.g., an outer peripheral surface) of the semiconductor stack STC. For example, the protective film INS may be located on the side surface of the first semiconductor layer SEM1, the side surface of the active layer MQW, and the side surface of the second semiconductor layer SEM2. In one or more embodiments, the protective film INS may further surround the side surface (e.g., an outer peripheral surface) of the third semiconductor layer SEM3.

The protective film INS may be a layer for protecting the side surface (e.g., an outer peripheral surface) of the light emitting element LE. For example, the protective film INS may be formed as an inorganic film such as silicon nitride (SiNx), silicon nitride oxide (SiON), silicon oxide (SiOx), titanium oxide (TiOx), and/or aluminum oxide (AlOx).

In one or more embodiments, the protective film INS may cover the side surface and the bottom surface of the conductive layer E1. An opening exposing a portion of the conductive layer E1 may be formed in the protective film INS. At the portion in which the conductive layer E1 is exposed, the conductive layer E1 may be in contact with the first contact electrode CTE1.

Further, a hole LEH that penetrates the conductive layer E1, the first semiconductor layer SEM1, and the active layer MQW to expose the second semiconductor layer SEM2 may be formed in the light emitting element LE. The hole LEH may have a circular planar shape, but the present disclosure is not limited thereto. For example, the hole LEH may have a polygonal planar shape such as an elliptical shape and/or a quadrilateral shape.

The protective film INS may be located on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS. At the portion in which the second semiconductor layer SEM2 is exposed, the second semiconductor layer SEM2 may be in contact with the second contact electrode CTE2.

The first contact electrode CTE1 may be located on the side surface of the protective film INS. For example, the first contact electrode CTE1 may be located on a portion of the protective film INS covering a portion of a side surface of each of the semiconductor stack STC and the conductive layer E1 and a portion of a bottom surface of the conductive layer E1. Accordingly, the first contact electrode CTE1 may be located at a portion of each of the side surface and the bottom surface of the light emitting element LE. For example, the first contact electrode CTE1 may be located on a portion of the side surface of each of the semiconductor stack STC and the conductive layer E1 and a portion of the bottom surface of the conductive layer E1, overlapping the pixel electrode PXE. The first contact electrode CTE1 may be located on the bottom surface of the conductive layer E1 that is exposed without being covered by the protective film INS, and may be electrically connected to the conductive layer E1. The first contact electrode CTE1 may be electrically connected to the first semiconductor layer SEM1 through the conductive layer E1. The conductive layer E1 of the light emitting element LE may be electrically connected to each of the pixel electrodes PXE through the first contact electrode CTE1 and a first connection electrode BE1.

The second contact electrode CTE2 may be spaced (e.g., spaced apart) from the first contact electrode CTE1 and located on the side surface of the protective film INS. For example, the second contact electrode CTE2 may be located on another portion of the protective film INS covering another portion of the side surface of each of the semiconductor stack STC and the conductive layer E1, and another portion of the bottom surface of the conductive layer E1. Accordingly, the second contact electrode CTE2 may be located at another portion of each of the side surface and the bottom surface of the light emitting element LE. For example, the second contact electrode CTE2 may be located on another portion of the side surface of each of the semiconductor stack STC and the conductive layer E1 and another portion of the bottom surface of the conductive layer E1, overlapping the common electrode CE. The second contact electrode CTE2 may also be located inside the hole LEH and may be located on the second semiconductor layer SEM2 that is exposed in the hole LEH without being covered by the protective film INS. Accordingly, the second contact electrode CTE2 may be electrically connected to the second semiconductor layer SEM2. The second semiconductor layer SEM2 may be electrically connected to the common electrode CE through the second contact electrode CTE2 and a second connection electrode BE2.

In one or more embodiments, each of the first contact electrode CTE1 and the second contact electrode CTE2 may be located on three side surfaces of the semiconductor stack STC. For example, when the semiconductor stack STC includes first to fourth side surfaces, the first contact electrode CTE1 may be located on the first side surface, the second side surface, and the third side surface of the semiconductor stack STC, and the second contact electrode CTE2 may be located on the second side surface, the third side surface, and the fourth side surface of the semiconductor stack STC.

Each of the first contact electrode CTE1 and the second contact electrode CTE2 may be formed as a transparent electrode through which light generated from the light emitting element LE may pass. For example, the first contact electrode CTE1 and the second contact electrode CTE2 may each have a light transmitting property that allows light in the visible light wavelength band generated from the light emitting element LE to pass through the first contact electrode CTE1 and the second contact electrode CTE2, and may be substantially transparent.

Each of the first contact electrode CTE1 and the second contact electrode CTE2 may include a transparent conductive material. For example, each of the first contact electrode CTE1 and the second contact electrode CTE2 may include a transparent conductive material having both conductivity and a light transmitting property. For example, each of the first contact electrode CTE1 and the second contact electrode CTE2 may include a transparent conductive oxide (TCO) having excellent conductivity and transparency, such as indium tin oxide (ITO) and/or indium zinc oxide (IZO). When the first contact electrode CTE1 and the second contact electrode CTE2 are formed concurrently(e.g., simultaneously), the first contact electrode CTE1 and the second contact electrode CTE2 may include the same transparent conductive material.

Because each of the first contact electrode CTE1 and the second contact electrode CTE2 is formed as a transparent electrode, the amount of light that passes through the first contact electrode CTE1 and the second contact electrode CTE2 to reach the reflective film RF may increase. Accordingly, the light emission ratio of each of the sub-pixels SPX may be increased by increasing reflected light Lrf reflected by the reflective film RF. For example, some of the light generated in the active layer MQW may pass through the first contact electrode CTE1 to reach the reflective film RF, and may be reflected by the reflective film RF to propagate to the upper side of the light emitting element LE, as indicated by the arrow in FIG. 7. Accordingly, the amount of light emitted from the sub-pixel SPX may increase, and the luminance and light efficiency of the sub-pixel SPX may be improved. On the other hand, when each of the first contact electrode CTE1 and the second contact electrode CTE2 is formed as an opaque electrode, light emitted in the lateral direction of the light emitting element LE toward the first contact electrode CTE1 and the second contact electrode CTE2 may not pass through the first contact electrode CTE1 and the second contact electrode CTE2. Accordingly, the light loss of the light emitting element LE may increase.

In one or more embodiments, the light emitting element LE may include light extraction patterns LEP formed on its one surface from which light is emitted. As an example, the light emitting element LE may include the light extraction patterns LEP formed on the top surface of the semiconductor stack STC (for example, the top surface of the third semiconductor layer SEM3). The light extraction patterns LEP may have a shape suitable for diffusing and/or scattering light on the top surface of the light emitting element LE. For example, the top surface of the light emitting element LE may be formed non-flat so that the top surface of the light emitting element LE has a shape suitable for light scattering. Accordingly, the light efficiency of the light emitting element LE (for example, the light emission ratio of light generated from the light emitting element LE) may be increased.

In one or more embodiments, the light emitting element layer may further include the first connection electrode BE1 and the second connection electrode BE2.

The first connection electrode BE1 may be located on a portion of the first organic layer 210 to electrically connect the first contact electrode CTE1 of the light emitting element LE and the pixel electrode PXE. For example, the first connection electrode BE1 of the first sub-pixel SPX1 may electrically connect the first contact electrode CTE1 of the first light emitting element LE1 and the first pixel electrode PXE1. The first connection electrode BE1 of the second sub-pixel SPX2 may electrically connect the first contact electrode CTE1 of the second light emitting element LE2 and the second pixel electrode PXE2. The first connection electrode BE1 of the third sub-pixel SPX3 may electrically connect the first contact electrode CTE1 of the third light emitting element LE3 and the third pixel electrode PXE3.

In one or more embodiments, the first connection electrode BE1 may be connected to the pixel electrode PXE through the first connection hole BH1 penetrating the first organic layer 210. Additionally, the first connection electrode BE1 may be located on the top surface of the first organic layer 210 and the first contact electrode CTE1.

The second connection electrode BE2 may be located on another portion of the first organic layer 210 and may electrically connect the second contact electrode CTE2 of the light emitting element LE and the common electrode CE. For example, the second connection electrode BE2 of the first sub-pixel SPX1 may electrically connect the second contact electrode CTE2 of the first light emitting element LE1 and the common electrode CE. The second connection electrode BE2 of the second sub-pixel SPX2 may electrically connect the second contact electrode CTE2 of the second light emitting element LE2 and the common electrode CE. The second connection electrode BE2 of the third sub-pixel SPX3 may electrically connect the second contact electrode CTE2 of the third light emitting element LE3 and the common electrode CE.

In one or more embodiments, the second connection electrode BE2 may be connected to the common electrode CE through the second connection hole BH2 penetrating the first organic layer 210. Additionally, the second connection electrode BE2 may be located on the top surface of the first organic layer 210 and the second contact electrode CTE2.

Each of the first connection electrode BE1 and the second connection electrode BE2 may include a conductive material. For example, each of the first connection electrode BE1 and the second connection electrode BE2 may include molybdenum (Mo), aluminum (Al), chromium (Cr), gold (Au), titanium (Ti), nickel (Ni), neodymium (Nd), and/or copper (Cu), and/or a transparent conductive material such as indium-tin oxide (ITO) and/or indium-zinc oxide (IZO).

In one or more embodiments, each of the first connection electrode BE1 and the second connection electrode BE2 may be formed to have a height close to the reflective film RF and may include a transparent conductive material. In this case, the amount of light reaching the reflective film RF from the light emitting element LE may be increased while sufficiently ensuring the contact area between the first connection electrode BE1 and the first contact electrode CTE1 and the contact area between the second connection electrode BE2 and the second contact electrode CTE2. Accordingly, the effect of improving the light emission ratio by the reflective film RF may be ensured or increased.

In one or more embodiments, each of the first connection electrode BE1 and the second connection electrode BE2 may be formed at a lower height, for example, at a lower height suitable for not blocking the light that passes through the first and second contact electrodes CTE1 and CTE2 to propagate toward the reflective film RF. Additionally, each of the first connection electrode BE1 and the second connection electrode BE2 may include a transparent conductive material or may include a metal material having high reflectivity, such as aluminum (Al). When each of the first connection electrode BE1 and the second connection electrode BE2 is located at a side surface lower layer of the light emitting element LE and includes a metal material with high reflectivity, light that propagates toward the side surface lower layer and/or the like of the light emitting element LE from among the light emitted from the active layer MQW of the light emitting element LE may be reflected by the connection electrodes BE to propagate in an upward direction of the light emitting element LE. Accordingly, the light emission ratio of the light emitting element LE may be increased.

The second organic layer 211 may cover a portion of the side surface of the light emitting elements LE and the connection electrodes BE. For example, the second organic layer 211 may be formed at a height lower than the height of the light emitting elements LE and may cover a portion of the side surface of the light emitting elements LE and the connection electrodes BE.

The second organic layer 211 may be formed as an organic layer such as acryl resin, epoxy resin, phenolic resin, polyamide resin, polyimide resin, and/or the like. The second organic layer 211 may alleviate the stepped portion caused by the light emitting elements LE.

The first capping layer CAP1 may be located on the light emitting elements LE and the second organic layer 211. The first capping layer CAP1 may include a material suitable for protecting the light emitting elements LE, for example, an inorganic insulating material.

The bank BNK may be located on the first capping layer CAP1. The bank BNK may be around (e.g., may surround) the light emitting elements LE at a position spaced (e.g., spaced apart) from the light emitting elements LE. For example, the bank BNK may include openings corresponding to emission areas (or light emitting element regions) in which the light emitting elements LE are located. The bank BNK may define transmission areas (e.g., emission areas of each of the sub-pixels SPX) through which light emitted from the light emitting elements LE may pass and light blocking areas (e.g., non-emission areas) surrounding the transmission areas. The bank layer BNK may include an organic film such as acryl resin, epoxy resin, phenolic resin, polyamide resin, polyimide resin, and/or the like, but is not limited thereto. In one or more embodiments, the bank BNK may include a light blocking material such as an inorganic black pigment such as carbon black, or an organic black pigment, and may also function as a light blocking layer. For example, the bank BNK may include a light blocking pattern including a light blocking material. The bank BNK may further include a capping layer (e.g., an inorganic film) covering the light blocking pattern.

The side surface of the bank BNK may include a curved surface or may include an inclined surface at a certain angle. The bank BNK may have a shape of which the width decreases as it goes to the upper layer, or a shape of which the width increases as it goes to the upper layer. Alternatively, the side surface of the bank BNK may have an entirely uniform width and be substantially perpendicular with respect to the substrate SUB. The side surface of the bank BNK may have other shapes as well. FIGS. 6 and 7 illustrate embodiments in which the side surface of the bank BNK includes a curved surface. The shape of the bank BNK may be variously changed depending on the formation material or process method of the bank BNK, and/or the light emission characteristics and/or the like of the sub-pixels SPX.

The reflective film RF may be located on the side surface of the bank BNK. FIGS. 6 and 7 illustrate embodiments in which the reflective film RF is located directly on the side surface of the bank BNK, but the present disclosure is not limited thereto. For example, in one or more embodiments, after an additional capping layer covering the bank BNK and the first capping layer CAP1 is formed, the reflective film RF may be located on a portion of the capping layer covering a side surface or the like of the bank BNK.

In one or more embodiments, the reflective film RF may be located also on the top surface of the bank BNK. Alternatively, the reflective film RF may not be located on the top surface of the bank BNK. FIGS. 6 and 7 illustrate an embodiment in which the reflective film RF is located on the side surface and the top surface of the bank BNK.

The reflective film RF may face the side surface of the light emitting element LE. The fact that the reflective film RF faces the side surface of the light emitting element LE may include a case where the reflective film RF faces at least a portion of the side surface of the light emitting element LE horizontally at the same height, and may further include a case where the reflective film RF faces the side surface of the light emitting element LE in a diagonal direction. For example, the reflective film RF may be located at a position and/or at a height at which light that has horizontally or diagonally passed through the side surface of the light emitting element LE on which the first contact electrode CTE1 and the second contact electrode CTE2 are located may reach.

The reflective film RF may reflect light that propagates in the lateral direction from the light emitting element LE and the light transmitting layer 212 and/or the like. The reflective film RF may include a material having high light reflectivity, for example, a metal such as aluminum (Al). Alternatively, the reflective film RF may be formed as a distributed Bragg reflector including inorganic films (for example, silicon nitride (SiNₓ), silicon nitride oxide (SiON), silicon oxide (SiOₓ), titanium oxide (TiOₓ), and/or aluminum oxide (AlOₓ)) having different refractive indices and arranged alternately.

The light transmitting layer 212 may be located on the light emitting elements LE and the first capping layer CAP1. In one or more embodiments, the light transmitting layer 212 may be formed to have a height equal to or greater than the height of the bank BNK and the reflective film RF and cover the bank BNK and the reflective film RF. For example, the light transmitting layer 212 may be formed entirely over the display area DA and cover the light emitting elements LE, the first capping layer CAP1, the bank BNK, and the reflective film RF. However, the present disclosure is not limited thereto, and the light transmitting layer 212 may be formed to have a height lower than or equal to the height of the bank BNK and the reflective film RF.

The light transmitting layer 212 may include an organic material. For example, the light transmitting layer 212 may be a light-transmissive organic film including epoxy resin, acrylic resin, cardo resin, and/or imide resin. The light transmitting layer 212 may also be referred to as a "third organic layer." The light transmitting layer 212 may alleviate or flatten the stepped portion caused by the light emitting elements LE and the bank BNK.

In one or more embodiments, the light emitting elements LE may emit light of a color corresponding to the emission color of each of the sub-pixels SPX, and the light transmitting layer 212 may transmit light emitted from the light emitting elements LE of the sub-pixels SPX. For example, the light transmitting layer 212 may transmit light of the first color, light of the second color, and light of the third color emitted from the first light emitting element LE1, the second light emitting element LE2, and the third light emitting element LE3. When the sub-pixels SPX include the light emitting elements LE that emit light corresponding to each emission color, the light emitted from the light emitting elements LE may be utilized more efficiently. For example, it is possible to prevent a decrease in the light efficiency of the sub-pixels SPX due to light conversion. Additionally, the color purity of light emitted from the sub-pixels SPX may be increased.

A second capping layer CAP2 may be located on the light transmitting layer 212. The second capping layer CAP2 may include an inorganic insulating material. The second capping layer CAP2 may be omitted.

Color filters may be located on the second capping layer CAP2 (or the light transmitting layer 212). The color filters may include a first color filter CF1, a second color filter CF2, and a third color filter CF3.

The first color filter CF1 may be located on the first light emitting element LE1 of the first sub-pixel SPX1. The first color filter CF1 may transmit light of the first color (e.g., red light) and absorb or block light of other colors (e.g., green light and blue light). Accordingly, the first sub-pixel SPX1 may emit light of the first color.

The second color filter CF2 may be located on the second light emitting element LE2 of the second sub-pixel SPX2. The second color filter CF2 may transmit light of the second color (e.g., green light) and absorb or block light of other colors (e.g., red light and blue light). Accordingly, the second sub-pixel SPX2 may emit light of the second color.

The third color filter CF3 may be located on the third light emitting element LE3 of the third sub-pixel SPX3. The third color filter CF3 may transmit light of the third color (e.g., blue light) and absorb or block light of other colors (e.g., red light and green light). Accordingly, the third sub-pixel SPX3 may emit light of the third color.

The first color filter CF1, the second color filter CF2, and the third color filter CF3 may overlap the bank BNK in the third direction DR3. For example, the first color filter CF1, the second color filter CF2, and the third color filter CF3 may overlap each other on the bank BNK and form a light blocking pattern.

A fourth organic layer 214 may be located on the color filters. The fourth organic layer 214 may be formed as an organic film including acryl resin, epoxy resin, phenolic resin, polyamide resin, polyimide resin, and/or the like. The fourth organic layer 214 may alleviate or flatten the stepped portion caused by the first color filter CF1, the second color filter CF2, and the third color filter CF3. For example, the top surface of the fourth organic layer 214 may be substantially flat.

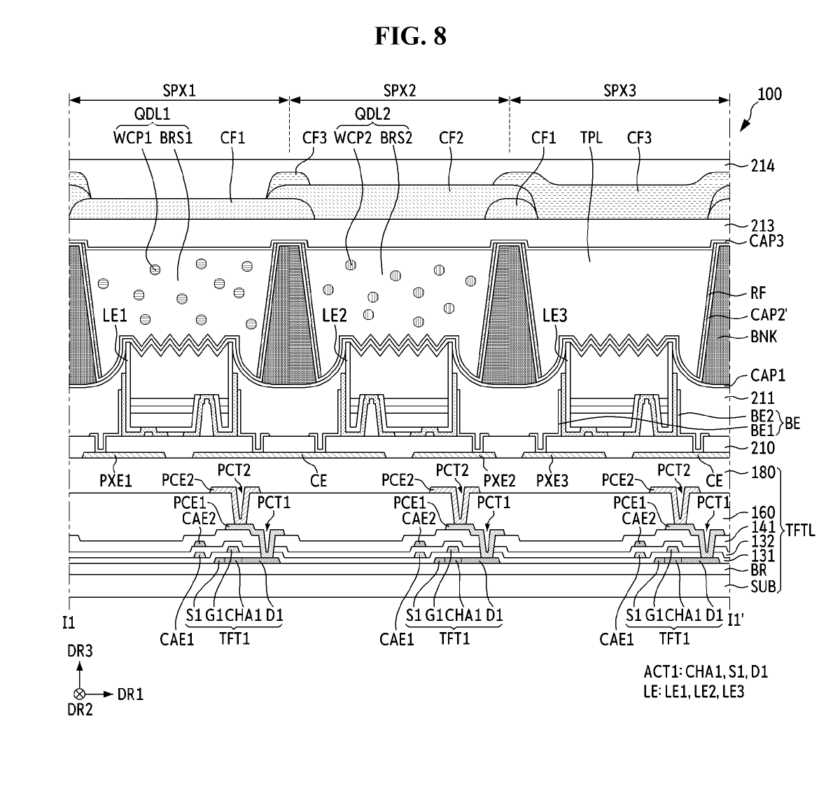

FIG. 8 is a cross-sectional view illustrating a display area of a display panel according to one or more embodiments. For example, FIG. 8 illustrates one embodiment of a cross-section of the pixel PX corresponding to the line I1-I1' of FIG. 5. Compared to FIG. 6, FIG. 8 illustrates an embodiment further including a light conversion layer. In describing the following embodiments, elements similar or identical to those of at least one embodiment described above are designated with the same reference numerals, and redundant descriptions will be omitted.

Referring to FIG. 8, the bank BNK, a second capping layer CAP2', and the reflective film RF may be located on the first capping layer CAP1. Additionally, a first light conversion layer QDL1, a second light conversion layer QDL2, a light transmitting layer TPL, a third capping layer CAP3, and a third planarization layer 213 may be located on the second capping layer CAP2'.

The bank BNK may be located on the first capping layer CAP1 and may be around (e.g., may surround) the light emitting elements LE, the first light conversion layer QDL1, the second light conversion layer QDL2, and the light transmitting layer TPL. The bank BNK may define respective transmission areas in which the first light conversion layer QDL1, the second light conversion layer QDL2, and the light transmitting layer TPL are located. The height of the bank BNK may be similar to or equal to the heights of the first light conversion layer QDL1, the second light conversion layer QDL2, and the light transmitting layer TPL. In one or more embodiments, the bank BNK may be formed as an organic film and may include a light blocking material.

FIG. 8 illustrates an embodiment in which the side surface of the bank BNK includes an inclined surface at a certain angle. However, the present disclosure is not limited thereto, and the side surface of the bank BNK may include a curved surface, as in the embodiments of FIGS. 6 and 7.

The second capping layer CAP2' may be located on the first capping layer CAP2 and the bank BNK. The second capping layer CAP2' may include an inorganic material suitable for encapsulating the light emitting element layer including the light emitting elements LE, and/or the first light conversion layer QDL1, the second light conversion layer QDL2, and the light transmitting layer TPL. The second capping layer CAP2' may be omitted.

The reflective film RF may be located on a portion of the second capping layer CAP2' covering the bank BNK. FIG. 8 illustrates an embodiment in which the reflective film RF is located only on the side surface of the bank BNK and is not located on the top surface of the bank BNK. However, the present disclosure is not limited thereto, and the reflective film RF may also be located on the top surface of the bank BNK.

The reflective film RF may face a side surface of each of the light emitting elements LE, the first light conversion layer QDL1, the second light conversion layer QDL2, and the light transmitting layer TPL. The reflective film RF may also face a part of the side surface of each of the light emitting elements LE. The reflective film RF may include a material with high light reflectivity or may be formed as a distributed Bragg reflector. The reflective film RF may reflect light traveling in the lateral direction from the light emitting elements LE, the first light conversion layer QDL1, the second light conversion layer QDL2, and the light transmitting layer TPL. Accordingly, the ratio of light emitted from the upper side of each of the sub-pixels SPX from among the light generated and/or converted in the sub-pixels SPX may be increased, so that the light emission ratio of the sub-pixels SPX may be improved.

The first light conversion layer QDL1 may be located on the first light emitting element LE1. In one or more embodiments, the first light emitting element LE1 may emit light of the third color (e.g., light in the blue wavelength band), and the first light conversion layer QDL1 may convert part of the light of the third color incident from the first light emitting element LE1 into light of the first color (e.g., light in the red wavelength band). The first light conversion layer QDL1 may include a first base resin BRS1 and a first wavelength conversion particle WCP1. The first base resin BRS1 may include a light-transmissive organic material. The first wavelength conversion particle WCP1 may convert part of the light of the third color incident from the first light emitting element LE1 into light of the first color. The first wavelength conversion particle WCP1 may be a quantum dot, a quantum rod, a fluorescent material, and/or a phosphorescent material. In one or more embodiments, the first light conversion layer QDL1 may further include light scatterers (e.g., particles capable of scattering or diffusing light, such as titanium dioxide (TiO₂) and/or silicon dioxide (SiO₂)).

The second light conversion layer QDL2 may be located on the second light emitting element LE2. In one or more embodiments, the second light emitting element LE2 may emit light of the third color, and the second light conversion layer QDL2 may convert part of the light of the third color incident from the second light emitting element LE2 into light of the second color (e.g., light in a green wavelength band). The second light conversion layer QDL2 may include a second base resin BRS2 and second wavelength conversion particles WCP2. The second base resin BRS2 may contain a light-transmissive organic material. The second wavelength conversion particle WCP2 may convert part of the light of the third color incident from the second light emitting element LE2 into light of the second color. The second wavelength conversion particle WCP2 may be a quantum dot, a quantum rod, a fluorescent material, and/or a phosphorescent material. In one or more embodiments, the second light conversion layer QDL2 may further include a light scatterer.

The light transmitting layer TPL may be located on the third light emitting element LE3. In one or more embodiments, the third light emitting element LE3 may emit light of the third color, and the light transmitting layer TPL may transmit light of the third color incident from the third light emitting element LE3 as it is. The light transmitting layer TPL may include a light-transmissive organic material. In one or more embodiments, the light transmitting layer TPL may further include a light scatterer. When the sub-pixels SPX include the light emitting elements LE that emit light of the same color, the manufacturing efficiency of the display panel 100 may be increased.

The third capping layer CAP3 may be located on the bank BNK, the second capping layer CAP2’, the reflective film RF, the first light conversion layer QDL1, the second light conversion layer QDL2, and the light transmitting layer TPL. The third capping layer CAP3 may include an inorganic material suitable for encapsulating the first light conversion layer QDL1, the second light conversion layer QDL2, and the light transmitting layer TPL. For example, the first light conversion layer QDL1, the second light conversion layer QDL2, and the light transmitting layer TPL may be encapsulated by the second capping layer CAP2' and the third capping layer CAP3. When the display panel 100 does not include the second capping layer CAP2', the first light conversion layer QDL1, the second light conversion layer QDL2, and the light transmitting layer TPL may be encapsulated by the first capping layer CAP1 and the third capping layer CAP3.

In one or more embodiments, each of the first capping layer CAP1, the second capping layer CAP2', and the third capping layer CAP3 may include an inorganic material. For example, each of the first capping layer CAP1, the second capping layer CAP2', and the third capping layer CAP3 may be formed as an inorganic film including silicon nitride (SiNx), silicon nitride oxide (SiON), silicon oxide (SiOx), titanium oxide (TiOx), and/or aluminum oxide (AlOx).

The third planarization layer 213 may be located on the third capping layer CAP3. Color filters (e.g., the first, second, and third color filters CF1, CF2, and CF3) and the fourth organic layer 214 may be located on the third planarization layer 213.

The third planarization layer 213 may be formed as an organic film including acryl resin, epoxy resin, phenolic resin, polyamide resin, polyimide resin, and/or the like. The third planarization layer 213 may also be referred to as a "fifth organic layer." The third planarization layer 213 may alleviate or flatten the stepped portion caused by the first color filter CF1, the second color filter CF2, and the third color filter CF3. For example, the top surface of the third planarization layer 213 may be substantially flat.

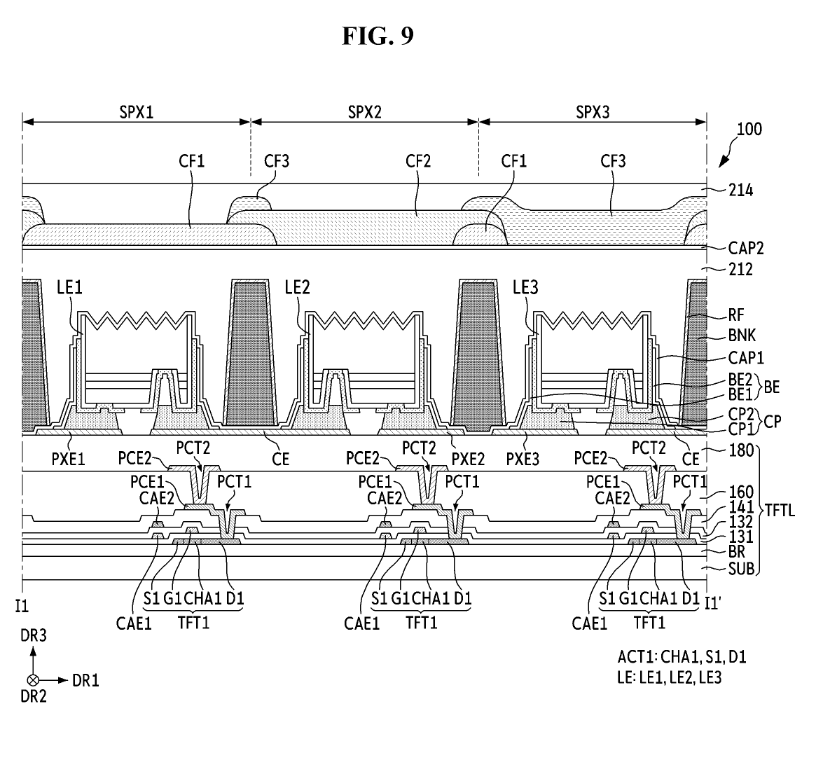

FIG. 9 is a cross-sectional view illustrating a display area of a display panel according to one or more embodiments. For example, FIG. 9 illustrates one embodiment of a cross-section of the pixel PX corresponding to the line I1-I1' of FIG. 5. Compared to FIG. 6, FIG. 9 illustrates an embodiment in which the display panel 100 further includes conductive patterns CP. Each of the embodiments disclosed in the present disclosure may be implemented or applied alone or in combination with at least one other embodiment.

Referring to FIG. 9, the display panel 100 may further include the conductive patterns CP located in each of the sub-pixels SPX. For example, the display panel 100 may further include a first conductive pattern CP1 located between the pixel electrode PXE and the light emitting element LE of each of the sub-pixels SPX, and a second conductive pattern CP2 located between the common electrode CE and the light emitting element LE of each of the sub-pixels SPX. The light emitting element LE of each of the sub-pixels SPX may be located on the first conductive pattern CP1 and the second conductive pattern CP2. In one or more embodiments, the light emitting element LE of each of the sub-pixels SPX may have a structure as illustrated in FIG. 7.

The first conductive pattern CP1 may be located between a portion of the pixel electrode PXE and a bottom surface of the first contact electrode CTE1 (see FIG. 7) of the light emitting element LE. The second conductive pattern CP2 may be located between a portion of the common electrode CE and a bottom surface of the second contact electrode CTE2 (see FIG. 7) of the light emitting element LE.

The first conductive pattern CP1 and the second conductive pattern CP2 may include a material suitable for bonding the light emitting element LE on the pixel electrode PXE and the common electrode CE. For example, the first conductive pattern CP1 and the second conductive pattern CP2 may include a conductive photoresist. For example, the first conductive pattern CP1 and the second conductive pattern CP2 may include a conductive photoresist including an organic material such as carbon black.

The light emitting element LE may be bonded onto the pixel electrode PXE and the common electrode CE by the first conductive pattern CP1 and the second conductive pattern CP2. Additionally, the light emitting element LE may be electrically connected to the pixel electrode PXE and the common electrode CE through the first conductive pattern CP1 and the second conductive pattern CP2, respectively. For example, the first conductive pattern CP1 may electrically connect the first contact electrode CTE1 of the light emitting element LE and the pixel electrode PXE, and the second conductive pattern CP2 may electrically connect the second contact electrode CTE2 of the light emitting element LE and the common electrode CE.

In one or more embodiments, the first contact electrode CTE1 of the light emitting element LE may be electrically connected to the pixel electrode PXE also through the first connection electrode BE1. Additionally, the second contact electrode CTE2 of the light emitting element LE may be electrically connected to the common electrode CE also through the second connection electrode BE2.

The first connection electrode BE1 may be located on another portion of the pixel electrode PXE, which is not covered with the first conductive pattern CP1. Another portion of the pixel electrode PXE may include a portion of the top surface of the pixel electrode PXE and/or a portion of a side surface of the pixel electrode PXE. The first connection electrode BE1 may be located also on the side surface of the first contact electrode CTE1 and the side surface of the first conductive pattern CP1. For example, the first connection electrode BE1 may be in contact with a portion of each of the top surface and the side surface of the pixel electrode PXE, the side surface of the first contact electrode CTE1, and the side surface of the first conductive pattern CP1. Accordingly, the first connection electrode BE1 may be electrically connected to the pixel electrode PXE, the first contact electrode CTE1, and the first conductive pattern CP1.

In one or more embodiments, the first connection electrode BE1 may be a transparent electrode including a transparent conductive material. Accordingly, light emitted in the lateral direction from the light emitting element LE may pass through the first contact electrode CTE1 and the first connection electrode BE1.

The second connection electrode BE2 may be located on another portion of the common electrode CE, which is not covered by the second conductive pattern CP2. Another portion of the common electrode CE may include a portion of the top surface of the common electrode CE. The second connection electrode BE2 may be located also on the side surface of the second contact electrode CTE2 and the side surface of the second conductive pattern CP2. For example, the second connection electrode BE2 may be in contact with a portion of the top surface of the common electrode CE, the side surface of the second contact electrode CTE2, and the side surface of the second conductive pattern CP2. Accordingly, the second connection electrode BE2 may be electrically connected to the common electrode CE, the second contact electrode CTE2, and the second conductive pattern CP2.

In one or more embodiments, the second connection electrode BE2 may be a transparent electrode including a transparent conductive material. Accordingly, light emitted in the lateral direction from the light emitting element LE may pass through the second contact electrode CTE2 and the second connection electrode BE2.

The display panel 100 according to the above-described embodiment may be manufactured by a hybrid bonding method utilizing the conductive patterns CP and the connection electrodes BE. For example, a method of manufacturing the display panel 100 according to one or more embodiments may include a step of bonding the light emitting element LE onto the pixel electrode PXE and the common electrode CE by using the first conductive pattern CP1 and the second conductive pattern CP2, and a step of strengthening the bonding of the light emitting element LE by forming the first connection electrode BE1 and the second connection electrode BE2.

The step of bonding the light emitting element LE onto the pixel electrode PXE and the common electrode CE by using the first conductive pattern CP1 and the second conductive pattern CP2 may include forming the first conductive pattern CP1 and the second conductive pattern CP2 on the pixel electrode PXE and the common electrode CE, respectively, and performing a bonding process such that the first conductive pattern CP1 and the second conductive pattern CP2 are bonded and/or connected to the first contact electrode CTE1 and the second contact electrode CTE2, respectively. For example, after applying a conductive photoresist on a pixel electrode layer including the pixel electrode PXE and the common electrode CE, a photolithography process may be performed to form the first conductive pattern CP1 and the second conductive pattern CP2 on the pixel electrode PXE and the common electrode CE, respectively. The first conductive pattern CP1 and the second conductive pattern CP2 may be formed separately from each other. Thereafter, the light emitting element LE may be bonded on the first conductive pattern CP1 and the second conductive pattern CP2.

In one or more embodiments, the conductive photoresist may be located only on a portion of each of the pixel electrode PXE and the common electrode CE including the region where the light emitting element LE is to be bonded, and may be removed on other portions of each of the pixel electrode PXE and the common electrode CE. Accordingly, the first conductive pattern CP1 and the second conductive pattern CP2 may be located only on a portion of each of the pixel electrode PXE and the common electrode CE, and may not cover other portions of each of the pixel electrode PXE and the common electrode CE. In one or more embodiments, when each of the pixel electrode PXE and the common electrode CE includes a reflective layer including a material with high reflectivity, the first conductive pattern CP1 and the second conductive pattern CP2 are locally located only in the bonding area, so that the light efficiency of the sub-pixel SPX may be further improved by increasing the reflectivity due to the pixel electrode PXE and the common electrode CE.

The step of forming the first connection electrode BE1 and the second connection electrode BE2 may include forming the first connection electrode BE1 on portions of the pixel electrode PXE, the first conductive pattern CP1, and the first contact electrode CTE1, and forming the second connection electrode BE2 on portions of the common electrode CE, the second conductive pattern CP2, and the second contact electrode CTE2. For example, the first connection electrode BE1 may be formed on a portion (e.g., a portion of the top surface of the pixel electrode PXE and/or a portion of the side surface of the pixel electrode PXE) of the pixel electrode PXE, which is not covered with the first conductive pattern CP1, the side surface of the first conductive pattern CP1, and the side surface of the first contact electrode CTE1, and the second connection electrode BE2 may be formed on a portion (e.g., a portion of the top surface of the common electrode CE and/or a portion of the side surface of the common electrode CE) of the common electrode CE, which is not covered with the second conductive pattern CP2, the side surface of the second conductive pattern CP2, and the side surface of the second contact electrode CTE2.

The light emitting element LE may be electrically connected between the pixel electrode PXE and the common electrode CE by the first conductive pattern CP1 and the second conductive pattern CP2, and may be electrically connected between the pixel electrode PXE and the common electrode CE also by the first connection electrode BE1 and the second connection electrode BE2. Accordingly, the contact resistance between the pixel electrode PXE and the light emitting element LE and the contact resistance between the common electrode CE and the light emitting element LE may be reduced, and the quality of the contact may be improved.

Accordingly, the light emitting element LE may be more stably located and connected between the pixel electrode PXE and the common electrode CE. For example, the light emitting element LE may be stably located and connected onto the pixel electrode PXE and the common electrode CE by a hybrid bonding structure and/or method utilizing the conductive patterns CP and the connection electrodes BE. The bottom surface (e.g., the bottom surfaces of the first contact electrode CTE1 and the second contact electrode CTE2) of the light emitting element LE may be bonded and/or connected onto the pixel electrode PXE and the common electrode CE by the conductive patterns CP, and the side surface (e.g., the side surfaces of the first contact electrode CTE1 and the second contact electrode CTE2) of the light emitting element LE may be connected to the pixel electrode PXE and the common electrode CE by the connection electrodes BE.

When the light emitting element LE is bonded onto the first conductive pattern CP1 and the second conductive pattern CP2, the first organic layer 210 of FIG. 6 may be omitted. Accordingly, the contact resistance may be prevented from increasing due to residues and/or the like of the first organic layer 210.

Additionally, also in the embodiment of FIG. 9, each of the first contact electrode CTE1 and the second contact electrode CTE2 of the light emitting element LE may be a transparent electrode including a transparent conductive material. Accordingly, from among the light emitted from the light emitting element LE, light reflected by the reflective film RF to be reflected in the upward direction of the sub-pixel SPX may be increased. As a result, the luminance and light efficiency of the sub-pixel SPX may be improved.

The first capping layer CAP1 may be located on the pixel electrode layer, the conductive patterns CP, the light emitting elements LE, and the connection electrodes BE. When the display panel 100 does not include the first organic layer 210 and the second organic layer 211 of FIG. 6, the first capping layer CAP1 may be located directly on the pixel electrode PXE and the common electrode CE around the first and second connection electrodes BE1 and BE2.

The bank BNK may be located on the first capping layer CAP1. The bank BNK may be formed with a height or thickness sufficient to be around (e.g., to surround) the light emitting elements LE. For example, the bank BNK may be formed with a height equal to or greater than the height of the light emitting elements LE, but is not limited thereto.

The reflective film RF may be located on the bank BNK. For example, the reflective film RF may be located on the side surface of the bank BNK, and may be optionally further located on the top surface of the bank BNK. The reflective film RF may be located directly on the bank BNK or may be located on a capping layer (e.g., the second capping layer CAP2' of FIG. 8) covering the bank BNK. The reflective film RF may face the side surfaces of the light emitting elements LE.

The light transmitting layer 212 (or a third organic layer) may be located on the light emitting elements LE, the first capping layer CAP1, the bank BNK, and the reflective film RF. In one or more embodiments, the second capping layer CAP2 may be located on the light transmitting layer 212. The second capping layer CAP2 may be omitted.

Color filters (e.g., the first, second, and third color filters CF1, CF2, and CF3) may be located on the second capping layer CAP2 (or the light transmitting layer 212). The fourth organic layer 214 may be located on the color filters.

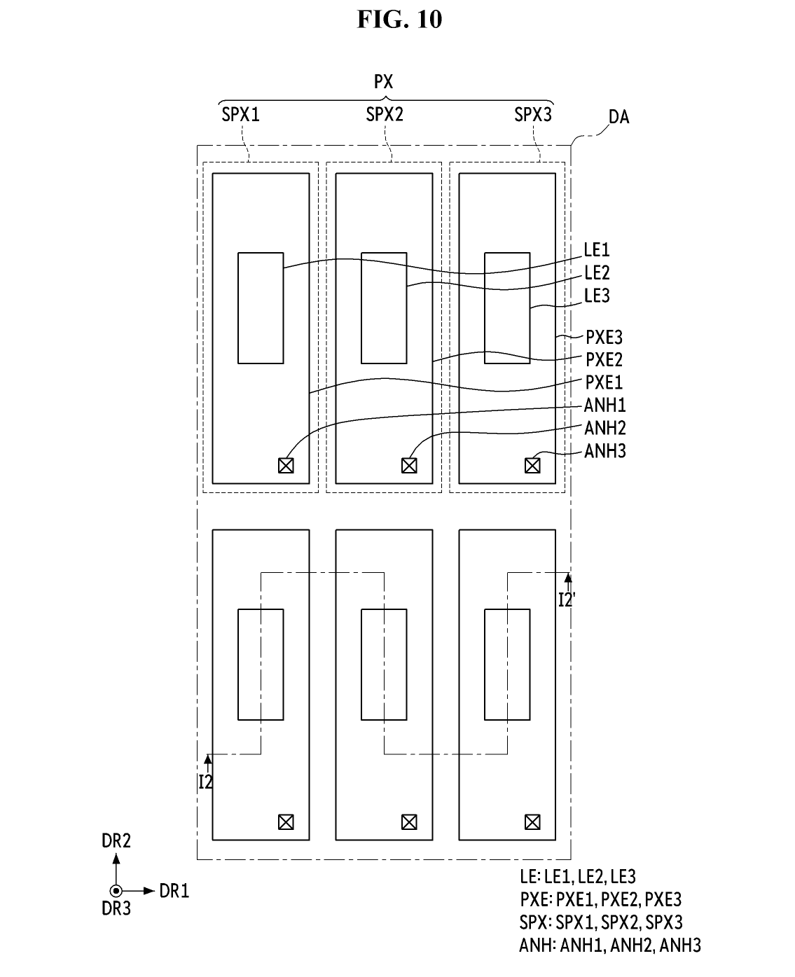

FIG. 10 is a plan view illustrating a display area of a display panel according to one or more embodiments. For example, FIG. 10 illustrates one embodiment of a layout structure of a light emitting element layer corresponding to a portion of the display area DA including two pixels PX. Compared with FIGS. 5 – 7, FIGS. 10 – 12 illustrate the display panel 100 including the vertical-type light emitting elements LE.

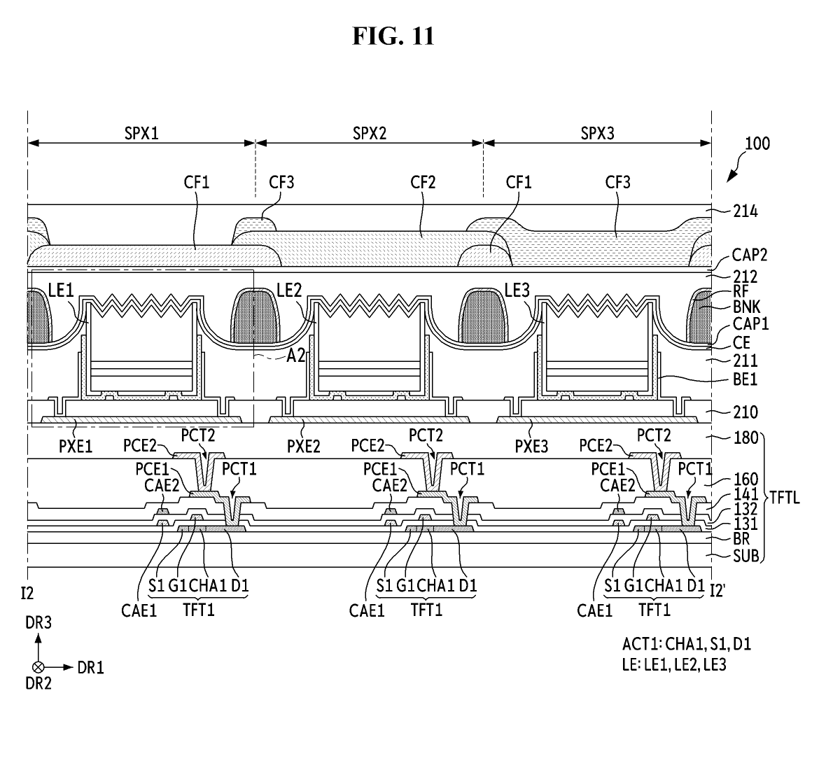

FIG. 11 is a cross-sectional view illustrating a display area of a display panel according to one or more embodiments. For example, FIG. 11 illustrates one embodiment of a cross-section of the pixel PX corresponding to the line I2-I2' of FIG. 10.

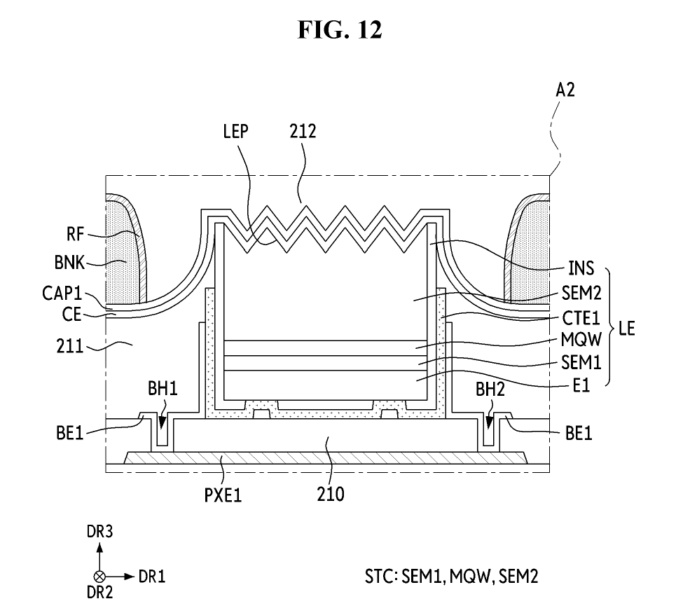

FIG. 12 is a cross-sectional view showing an area A2 of FIG. 11 in detail. For example, FIG. 12 illustrates the light emitting element LE according to one or more embodiments, for example, the first light emitting element LE1 located in area A1 of FIG. 11 in detail. In one or more embodiments, the first light emitting element LE1, the second light emitting element LE2, and the third light emitting element LE3 may have substantially the same cross-sectional structure.

Referring to FIGS. 10 – 12, each of the sub-pixels SPX may include the pixel electrode PXE, the light emitting element LE located on the pixel electrode PXE, and the common electrode CE located on the light emitting element LE. In one or more embodiments, the pixel electrode PXE may be individually located in each sub-pixel area, and the common electrode CE may be formed as a common layer that is located entirely across the display area DA. The first capping layer CAP1 may be located on the common electrode CE.

The light emitting element LE of each of the sub-pixels SPX may include the first contact electrode CTE1 located on the side surface of each of the semiconductor stack STC and the conductive layer E1 and the bottom surface of the conductive layer E1. FIG. 12 discloses an embodiment in which the first contact electrode CTE1 covers the entire bottom surface of the conductive layer E1, but the present disclosure is not limited thereto. For example, the first contact electrode CTE1 may cover only a portion of the bottom surface of the conductive layer E1. The first contact electrode CTE1 may be in contact with the conductive layer E1 at a portion of the bottom surface of the conductive layer E1, which is not covered with the protective film INS. Accordingly, the first contact electrode CTE1 may be electrically connected to the conductive layer E1.

The first connection electrode BE1 may be located on the side surface of the first contact electrode CTE1. The first connection electrode BE1 may electrically connect the pixel electrode PXE and the first contact electrode CTE1. In one or more embodiments, the first connection electrode BE1 may be electrically connected to the pixel electrode PXE through a plurality of connection holes including the first connection hole BH1 and the second connection hole BH2. In one or more embodiments, the first connection electrode BE1 may be formed as a single integrated pattern to be around (e.g., to surround) the side surface of the light emitting element LE, or may be formed as a plurality of divided patterns. For example, in FIG. 12, the first connection electrode BE1 located on the left side of the light emitting element LE and the first connection electrode BE1 located on the right side of the light emitting element LE may be formed as one pattern that is connected, or may be formed as separate divided patterns that are separated from each other.

The light emitting element LE may not include the hole LEH and the second contact electrode CTE2 disclosed in FIG. 7. In one or more embodiments, the light emitting element LE may not also include the third semiconductor layer SEM3 of FIG. 7, but the present disclosure is not limited thereto. The common electrode CE may be located on the second semiconductor layer SEM2. Accordingly, the second semiconductor layer SEM2 may be electrically connected to the common electrode CE.

FIG. 12 discloses an embodiment in which the common electrode CE is directly located on the second semiconductor layer SEM2, but the present disclosure is not limited thereto. For example, the light emitting element LE may further include at least one semiconductor layer and/or conductive layer located between the second semiconductor layer SEM2 and the common electrode CE. In this case, the second semiconductor layer SEM2 and the common electrode CE may be electrically connected to each other via at least one semiconductor layer and/or conductive layer.

In addition, FIGS. 10 – 12 illustrate the display panel 100 in which the vertical-type light emitting element LE is connected to the pixel electrode PXE by the first connection electrode BE1, but the present disclosure is not limited thereto. For example, the vertical-type light emitting element LE may be bonded onto the pixel electrode PXE by the hybrid bonding structure and/or method described in the embodiment of FIG. 9. In this case, the conductive pattern CP (see FIG. 9) (e.g., the first conductive pattern CP1) may be formed on the pixel electrode PXE, and the light emitting element LE may be bonded onto the pixel electrode PXE by using the conductive pattern CP. Thereafter, the first connection electrode BE1 may be formed on a portion of the pixel electrode PXE, which is not covered by the conductive pattern CP, the side surface of the conductive pattern CP, and the side surface of the first contact electrode CTE1, so that the connection between the pixel electrode PXE and the light emitting element LE may be strengthened.

As described above, the display device 1 according to one or more embodiments may include the light emitting element LE including a contact electrode located on a side surface thereof, and the contact electrode may be formed as a transparent electrode including a transparent conductive material. For example, the display device 1 according to one or more embodiments may include the flip-type light emitting element LE including the first contact electrode CTE1 and the second contact electrode CTE2 that are located separately from each other on the side surface of the light emitting element LE, or the vertical-type light emitting element LE including the first contact electrode CTE1 located at the side surface of the light emitting element LE. Accordingly, the amount of light emitted from the light emitting element LE may be increased, and the luminance and light efficiency of the light emitting element LE may be improved. For example, from among the light generated in the active layer MQW of the light emitting element LE, light that has propagated in the lateral direction of the light emitting element LE may pass through the contact electrode (e.g., the first contact electrode CTE1 and/or the second contact electrode CTE2) to be emitted to the outside of the light emitting element LE.

In one or more embodiments, the display device 1 may further include the reflective film RF facing the side surface of the light emitting element LE. By reflecting light that has propagated in the lateral direction of the light emitting element LE by the reflective film RF, the luminance and light efficiency of the sub-pixel SPX may be improved. For example, part of the light that has passed through the first contact electrode CTE1 and/or the second contact electrode CTE2 to be emitted from the light emitting element LE may be reflected by the reflective film RF to propagate in the front direction (e.g., the third direction DR3) of the display device 1.

According to one or more embodiments described above, the luminance and light efficiency of the sub-pixel SPX and the display device 1 including the same may be improved.

In one or more embodiments, the display device 1 may further include the conductive pattern CP located between a pixel electrode layer including the pixel electrode PXE and/or the common electrode CE and the light emitting element LE, and the light emitting element LE may be bonded onto the pixel electrode PXE and/or the common electrode CE by the conductive pattern CP. Additionally, the first connection electrode BE1 and/or the second connection electrode BE2 may be further located at the side surface of the light emitting element LE.

According to one or more embodiments described above, the light emitting element LE may be more stably located and/or connected between the pixel electrode PXE and the common electrode CE. For example, the light emitting element LE may be more stably bonded onto a pixel electrode layer by the conductive pattern CP and the connection electrode BE, and the contact resistance between the pixel electrode layer and the light emitting element LE may be reduced.

The display device 1 according to at least one of the above-described embodiments may be applied to various electronic devices. The electronic device according to one or more embodiments may include the above-described display device 1 (or a display module including the display panel 100 according to at least one embodiment), and may further include modules or devices having other additional functions in addition to the display device 1.

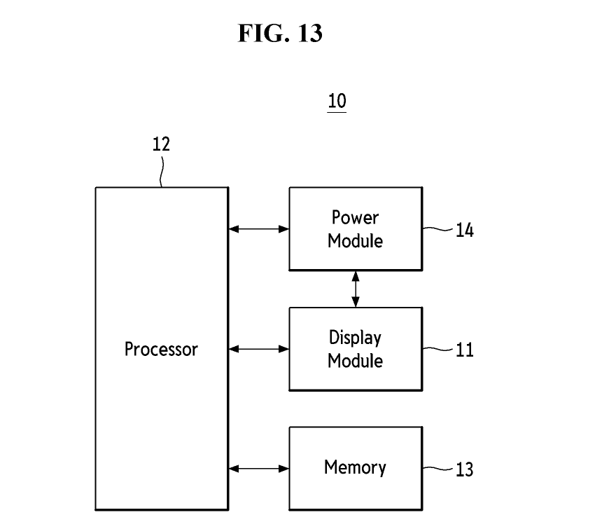

FIG. 13 is a block diagram of an electronic device according to one or more embodiments. Referring to FIG. 13, an electronic device 10 according to one or more embodiments may include a display module 11, a processor 12, a memory 13, and a power module 14.

The electronic device 10 may output various information in the form of images through the display module 11. For example, when the processor 12 executes an application stored in the memory 13, image information provided by the application may be provided to a user through the display module 11.

The display module 11 may include the display panel 100 for displaying an image. For example, the display module 11 may include the display panel 100 according to at least one of the aforementioned embodiments.

The processor 12 may include at least one of a central processing unit (CPU), an application processor (AP), a graphic processing unit (GPU), a communication processor (CP), an image signal processor (ISP), or a controller.

The memory 13 may store data information required for the operation of the processor 12 or the display module 11. For example, the memory 13 may store an image data signal and/or an input control signal.

The processor 12 may control the display module 11 using information stored in the memory 13. The processor 12 may transmit the image data signal and/or the input control signal stored in the memory 13 to the display module 11. For example, when the processor 12 executes an application stored in the memory 13, an image data signal and/or an input control signal is transmitted to the display module 11, and the display module 11 may process the received signal and output image information through a display screen.

The power module 14 may include a power supply module, such as a power adapter and/or a battery device, and a power conversion module that converts power supplied by the power supply module to generate power required for the operation of the electronic device 10.

At least one of the components of the electronic device 10 described above may be included in the display device 1 according to one or more embodiments described above. Further, some of individual modules functionally included in one module may be included in the display device 1 and some others may be provided separately from the display device 1. For example, the display device 1 may include the display module 11, and the processor 12, the memory 13, and the power module 14 may be provided in the form of other devices in the electronic device 10 other than the display device 1.

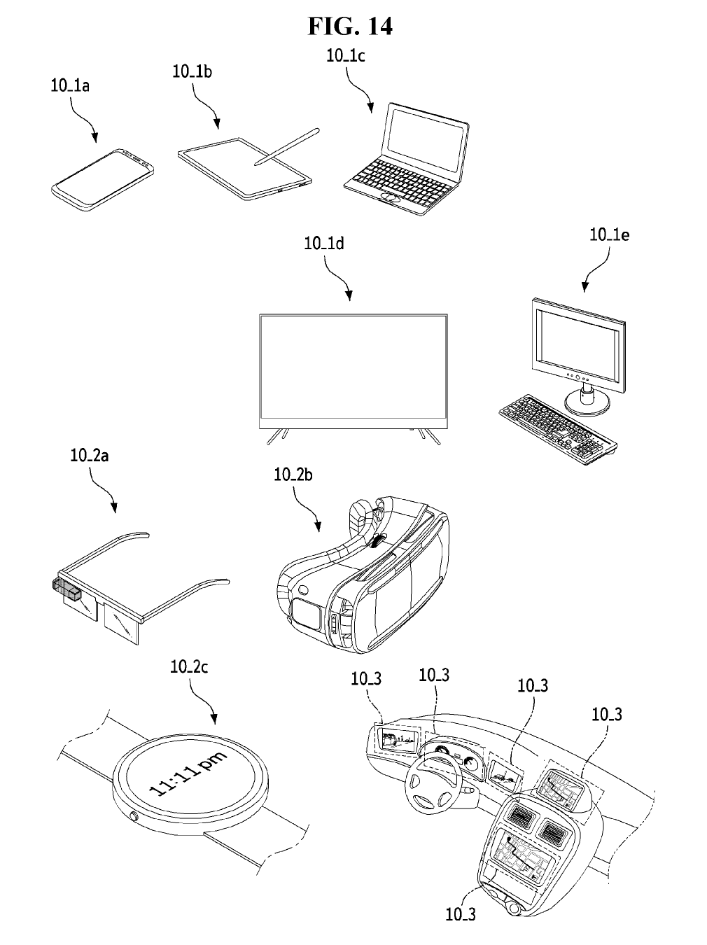

FIG. 14 is schematic views of electronic devices according to various embodiments.

Referring to FIG. 14, various electronic devices to which the display device 1 according to one or more embodiments is applied may include not only an image display electronic device such as a smartphone 10_1a, a tablet PC 10_1b, a laptop 10_1c, a TV 10_1d, and a desk monitor 10_1e, but also a wearable electronic device including a display module, such as smart glasses 10_2a, a head mounted display 10_2b, or a smart watch 10_2c, a vehicle electronic device 10_3 including a display module, such as a center fascia, and a dashboard of an automobile, a center information display (CID) placed on the dashboard, a room mirror display, and the like.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a pixel electrode located on a substrate; and
a light emitting element located on the pixel electrode and electrically connected to the pixel electrode,
wherein the light emitting element comprises:
a semiconductor stack comprising a first semiconductor layer, an active layer, and a second semiconductor layer;
a protective film covering a side surface of the semiconductor stack; and
a first contact electrode located on a side surface of the protective film and electrically connected to the first semiconductor layer,
wherein the first contact electrode comprises a transparent conductive material.

2. The display device of claim 1, further comprising:
a bank spaced from the light emitting element and around the light emitting element; and
a reflective film located on a side surface of the bank.

3. The display device of claim 2, wherein the reflective film faces the side surface of the light emitting element.

4. The display device of claim 1, wherein the first contact electrode comprises indium-tin oxide or indium-zinc oxide.

5. The display device of claim 1, wherein the first contact electrode is located on a portion of each of a side surface and a bottom surface of the light emitting element.

6. The display device of claim 5, further comprising:
a first conductive pattern located between a portion of the pixel electrode and a bottom surface of the first contact electrode; and
a first connection electrode located on another portion of the pixel electrode, a side surface of the first contact electrode, and a side surface of the first conductive pattern.

7. The display device of claim 6, wherein the light emitting element further comprises a second contact electrode located on another portion of each of the side surface and the bottom surface of the light emitting element and is electrically connected to the second semiconductor layer, and
wherein the second contact electrode comprises a transparent conductive material.

8. The display device of claim 7, further comprising:
a common electrode located on the substrate and spaced from the pixel electrode;
a second conductive pattern located between a portion of the common electrode and a bottom surface of the second contact electrode; and
a second connection electrode located on another portion of the common electrode, a side surface of the second contact electrode, and a side surface of the second conductive pattern.

9. The display device of claim 8, wherein the first conductive pattern and the second conductive pattern comprise a conductive photoresist.

10. The display device of claim 9, wherein the first conductive pattern and the second conductive pattern comprise carbon black.

11. The display device of claim 8, wherein the first connection electrode and the second connection electrode comprise a transparent conductive material.

12. The display device of claim 1, further comprising:
an organic layer located between the pixel electrode and the light emitting element and covering a portion of the pixel electrode; and
a first connection electrode located on a portion of the organic layer and electrically connecting the pixel electrode and the first contact electrode.

13. The display device of claim 1, wherein the light emitting element further comprises a second contact electrode located on the side surface of the protective film, spaced from the first contact electrode, and electrically connected to the second semiconductor layer, and
wherein the second contact electrode comprises a transparent conductive material.

14. The display device of claim 13, further comprising:
a common electrode located on the substrate and spaced from the pixel electrode;
an organic layer covering a portion of the common electrode and the pixel electrode and located below the light emitting element;
a first connection electrode located on a portion of the organic layer and electrically connecting the pixel electrode and the first contact electrode; and
a second connection electrode located on another portion of the organic layer and electrically connecting the common electrode and the second contact electrode.

15. An electronic device comprising:
a display module comprising a display panel; and
a processor configured to transmit an image data signal to the display module,
wherein the display panel comprises:
a pixel electrode located on a substrate; and
a light emitting element located on the pixel electrode and electrically connected to the pixel electrode,
wherein the light emitting element comprises:
a semiconductor stack comprising a first semiconductor layer, an active layer, and a second semiconductor layer;
a protective film covering a side surface of the semiconductor stack; and
a first contact electrode located on a side surface of the protective film and electrically connected to the first semiconductor layer, the first contact electrode comprising a transparent conductive material.

16. The electronic device of claim 15, wherein the display panel further comprises:
a bank spaced from the light emitting element and around the light emitting element; and
a reflective film located on a side surface of the bank.

17. The electronic device of claim 15, wherein the first contact electrode is located on a portion of each of a side surface and a bottom surface of the light emitting element, and
wherein the display panel further comprises:
a first conductive pattern located between a portion of the pixel electrode and a bottom surface of the first contact electrode; and
a first connection electrode located on another portion of the pixel electrode, a side surface of the first contact electrode, and a side surface of the first conductive pattern.

18. The electronic device of claim 17, wherein the first conductive pattern comprises a conductive photoresist.

19. The electronic device of claim 15, wherein the light emitting element further comprises a second contact electrode located on the side surface of the protective film, spaced from the first contact electrode, and electrically connected to the second semiconductor layer, and
wherein the second contact electrode comprises a transparent conductive material.

20. The electronic device of claim 19, wherein the display panel further comprises:
a common electrode located on the substrate and spaced from the pixel electrode;
a first connection electrode located on the pixel electrode and electrically connecting the pixel electrode and the first contact electrode; and
a second connection electrode located on the common electrode and electrically connecting the common electrode and the second contact electrode.
